(19) United States
(12) Patent Application Publication
(10) Pub. No.: US 2023/0354659 A1
(43) Pub. Date: Nov. 2, 2023

(54) DISPLAY PANEL AND DISPLAY DEVICE

(71) Applicant: LG Display Co., Ltd., Seoul (KR)

(72) Inventor: YuHo JUNG, Gyeonggi-do (KR)

(21) Appl. No.: 18/188,286

(22) Filed: Mar. 22, 2023

(30) Foreign Application Priority Data
Apr. 29, 2022 (KR) 10-2022-0053306

(51) Int. Cl. H10K 59/131; G09G 3/32; H10K 59/40; H10K 59/65; H10K 59/121; H10K 59/123; H10K 59/124; H10K 59/80

(52) U.S. Cl. CPC H10K 59/131; G09G 3/32; H10K 59/40; H10K 59/65; H10K 59/1213; H10K 59/123; H10K 59/124; H10K 59/873; G09G 2300/0852; G09G 2300/0426

(57) ABSTRACT

Provided is a display device including a display panel including a display area including a first optical area, the first optical area including a central area and a bezel area located outside of the central area, and a normal area located outside of the first optical area. The display panel includes a plurality of emitting devices disposed in the central area, a plurality of emitting devices disposed in the bezel area, and a plurality of transistors disposed in the bezel area and including a plurality of source-drain electrode patterns. A connection pattern extends from the bezel area to a portion of the central area. The connection pattern is located below at least one of the source-drain electrode patterns and in contact with the source-drain electrode patterns.

### CROSS REFERENCE TO RELATED APPLICATION

This application claims priority from Korean Patent Application No. 10-2022-0053306, filed on Apr. 29, 2022, which is hereby incorporated by reference for all purposes as if fully set forth herein.

### BACKGROUND

### Technical Field

Embodiments relate to a display panel and a display device and, more particularly, to a display panel and a display device able to simplify processing while improving the transmittance of an area in which an optical device is disposed.

### Description of the Related Art

Along with technological development, a display device may provide an image capturing function, a variety of detection functions, or the like, in addition to an image display function. In this regard, the display device is required to be provided with an optoelectronic device (also referred to as a light receiving device or a sensor) such as a camera or a detection sensor.

The optoelectronic device is required to receive light from the front surface of the display device and accordingly, be disposed in a location in which light reception is advantageous. Thus, conventionally, a camera (more particularly, a camera lens) and a detection sensor have been disposed on the front surface of a display device so as to be disclosed externally. As a result, the bezel of the display panel may be widened or a notch or a physical hole may be formed in a display area of the display panel in order to accommodate the camera or the detection sensor.

As an optoelectronic device, such as a camera or a detection sensor, performing a predetermined function by receiving light may be disposed on the display device, the size of the bezel on the front surface of the display device may be increased or a degree of design freedom of the front surface of the display device may be limited.

### BRIEF SUMMARY

In the display technology field, research into technology enabling a display to be provided with an optoelectronic device, such as a camera and a detection sensor, without reducing the size of a display area of a display panel has been undertaken. In this regard, the inventors of the present disclosure have invented a display panel and a display device having a light transmission structure by which an optoelectronic device provided below a display area of the display panel may normally receive light without being exposed on the front of the display device.

In addition, the inventors of the present disclosure have invented a display panel and a display device having high transmittance in an area in which the optoelectronic device is disposed.

Embodiments of the present disclosure may provide a display panel and a display device in which an optoelectronic device, such as a camera and a detection sensor, may be provided below the display panel to reduce a non-display area of the display panel while being disposed so as not to be exposed on the front of the display device.

Embodiments of the present disclosure may provide a display panel and a display device having a light transmission structure by which the optoelectronic device located below the display area of the display panel may normally receive light.

The objective of the present disclosure is not limited to the aforementioned description, and other objectives not explicitly disclosed herein will be clearly understood by those having ordinary knowledge in in the art from the description provided hereinafter.

According to embodiments of the present disclosure, a display device according to embodiments of the present disclosure may include a display panel including a display area including a first optical area, the first optical area including a central area and a bezel area located in the optical area, but outside of the central area, and a normal area located outside of the first optical area. The display panel may include a plurality of emitting devices disposed in the central area, a plurality of emitting devices disposed in the bezel area, and a plurality of transistors disposed in the bezel area and including a plurality of source-drain electrode patterns. A connection pattern may extend from the bezel area to a portion of the central area. The connection pattern may be located below at least one of the source-drain electrode patterns and in contact with the source-drain electrode patterns.

According to embodiments, in the display panel and the display device, the optoelectronic device, such as a camera and a detection sensor, may be provided below the display area of the display panel to reduce a non-display area of the display panel while being disposed so as not to be exposed on the front of the display device.

In addition, according to embodiments, in the display panel and the display device, the plurality of transistors may be disposed in the bezel area of the optical area while not being disposed in the central area of the optical area so as to improve the transmittance of the central area.

In addition, according to embodiments, in the display panel and the display device, when the source-drain electrode pattern of the transistor disposed in the optical area and the connection pattern are formed, a source-drain electrode material is continuously deposited after depositing a connection pattern material before the deposition of the source-drain electrode material. The source-drain electrode pattern and the connection pattern may be formed by simultaneously performing patterning using a half tome mask after the connection pattern material and the source-drain electrode material are deposited. Thus, an insulating film disposed between the source-drain electrode pattern and the connection pattern may be omitted, thereby reducing the thickness and obtaining process simplification.

In addition, according to embodiments, the display panel and the display device may have a light transmission structure by which the optoelectronic device located below the display area of the display panel may normally receive light.

In addition, according to embodiments, in the display panel and the display device, normal display driving may be enabled in an optical area included in the display area of the display panel, with the optoelectronic device overlapping the optical area.

It is to be understood that the foregoing description including the objectives, embodiments, and effects of the present disclosure does not specify essential limitations of the appended Claims, and thus the scope of the Claims is not restricted by the foregoing description and the following detailed description of the present disclosure.

### DESCRIPTION OF THE SEVERAL VIEWS OF THE DRAWINGS

The above and other objectives, features, and advantages of the present disclosure will be more clearly understood from the following detailed description, taken in conjunction with the accompanying drawings, in which:

FIGS. 1A, 1B, 1C, and 1D are plan diagrams illustrating a display device according to embodiments of the present disclosure;

FIG. 2 is a diagram illustrating a system configuration of the display device according to embodiments of the present disclosure;

FIG. 3 is an equivalent circuit diagram of a subpixel in the display panel according to embodiments of the present disclosure;

FIG. 4 is a layout diagram of subpixels in three areas in the display area of the display panel according to embodiments of the present disclosure;

FIG. 5A is a layout diagram of signal lines in the first optical area and the normal area in the display panel according to embodiments of the present disclosure;

FIG. 5B is a layout diagram of signal lines in the second optical area and the normal area in the display panel according to embodiments of the present disclosure;

FIGS. 6 and 7 are cross-sectional diagrams of the normal area, the first optical area, and the second optical area included in the display area of the display panel according to embodiments of the present disclosure;

FIG. 8 is a cross-sectional diagram of a peripheral portion of the display panel according to embodiments of the present disclosure;

FIG. 9 is a plan diagram of the first optical area of the display device according to embodiments of the present disclosure;

FIG. 10 is an enlarged diagram of area X in FIG. 9;

FIGS. 11 and 12 are diagrams illustrating portions of the normal area and the first optical area included in the display area of the display device according to embodiments of the present disclosure having the routing structure; and

FIGS. 13A to 13F are diagrams illustrating a mask process of area A in FIG. 11.

### DETAILED DESCRIPTION

The advantages and features of the present disclosure and methods of the realization thereof will be apparent with reference to the accompanying drawings and detailed descriptions of embodiments. The present disclosure should not be construed as being limited to the embodiments set forth hereinafter and may be embodied in a variety of different forms. Rather, these embodiments are provided so that the present disclosure will be thorough and complete, and will fully convey the scope of the present disclosure to those having ordinary knowledge in the technical field. The scope of the present disclosure shall be defined by the appended Claims.

The shapes, sizes, dimensions (e.g., length, width, height, thickness, radius, diameter, area, etc.), ratios, angles, numbers, number of elements and the like, inscribed in the drawings to illustrate embodiments are illustrative only, and the present disclosure is not limited to the embodiments illustrated in the drawings. Throughout this document, the same reference numerals and symbols will be used to designate the same or like components.

A dimension including size and a thickness of each component illustrated in the drawing are illustrated for convenience of description, and the present disclosure is not limited to the size and the thickness of the component illustrated. However, it is to be noted that the relative dimensions including the relative size, location, and thickness of the components illustrated in various drawings submitted herewith are part of the present disclosure.

In the following description of the present disclosure, detailed descriptions of known functions and components incorporated into the present disclosure will be omitted when it is determined that the description may make the subject matter in some embodiments of the present disclosure rather unclear. It will be understood that the terms “comprise,” “include,” “have,” and any variations thereof used herein are intended to cover non-exclusive inclusions unless explicitly stated to the contrary. Descriptions of components in the singular form used herein are intended to include descriptions of components in the plural form, unless explicitly stated to the contrary.

In the analysis of a component, it shall be understood that an error range is included therein, even in the situation in which there is no explicit description thereof.

When spatially relative terms, such as “on,” “above,” “under,” “below,” and “on a side of,” are used herein for descriptions of relationships between one element or component and another element or component, one or more intervening elements or components may be present between the one and other elements or components, unless a term, such as “immediately” or “directly,” is used.

When time relative terms, such as “after,” “subsequent to,” “next,” “before,” and the like, are used to describe temporal precedence relationships, these terms may be used to describe non-consecutive or non-sequential cases unless the term “directly” or “immediately” is used therewith.

It will be understood that when an element or a layer is referred to as being formed “on” another element or layer, not only can it be directly located on the other element or layer, but it can also be indirectly located on the other element or layer via an intervening element or layer.

In addition, terms, such as “first” and “second” may be used herein to describe a variety of components. It should be understood, however, that these components are not limited by these terms. These terms are merely used to discriminate one element or component from other elements or components. Thus, a first component referred to as first hereinafter may be a second component within the spirit of the present disclosure.

In designating elements of the drawings by reference numerals, the same elements will be designated by the same reference numerals although they are shown in different drawings.

In the drawings, size and thickness of each element are illustrated for convenience in description, and the present disclosure is not necessarily limited to those illustrated in the drawings.

The features of embodiments of the present disclosure may be partially or entirely coupled or combined with each other and, as will be apparent to those having ordinary knowledge in in the art, may work in concert with each other or may operate in a variety of technical methods. In addition, respective embodiments may be carried out independently or may be associated with and carried out in concert with other embodiments.

Hereinafter, a display panel and a display device according to a variety of embodiments of the present disclosure will be described in detail with reference to the accompanying drawings.

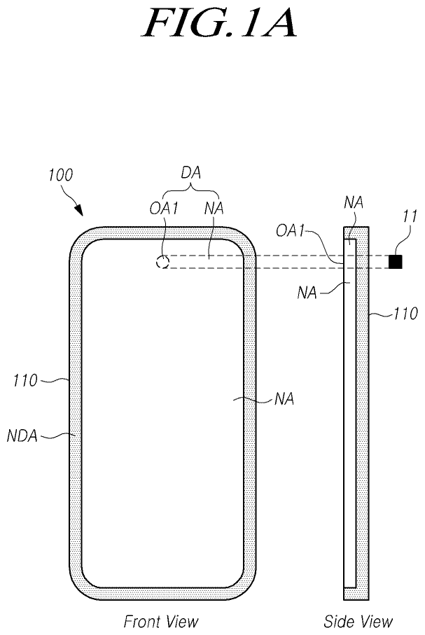

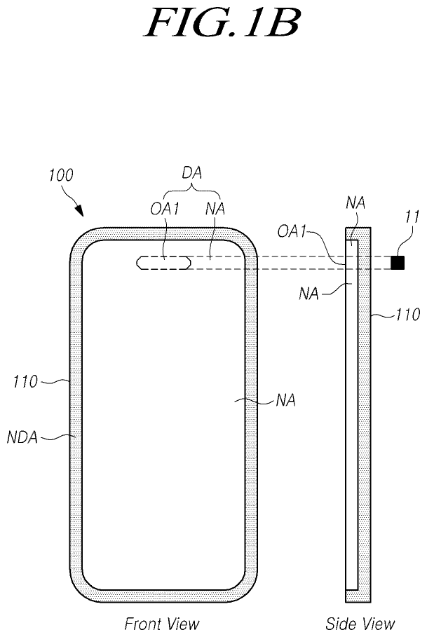

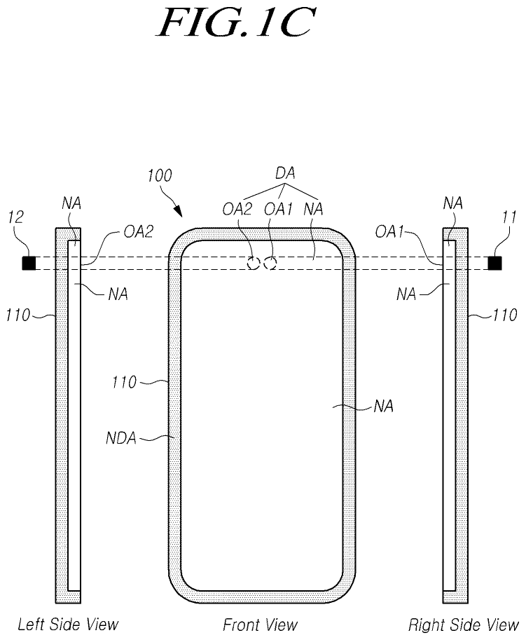

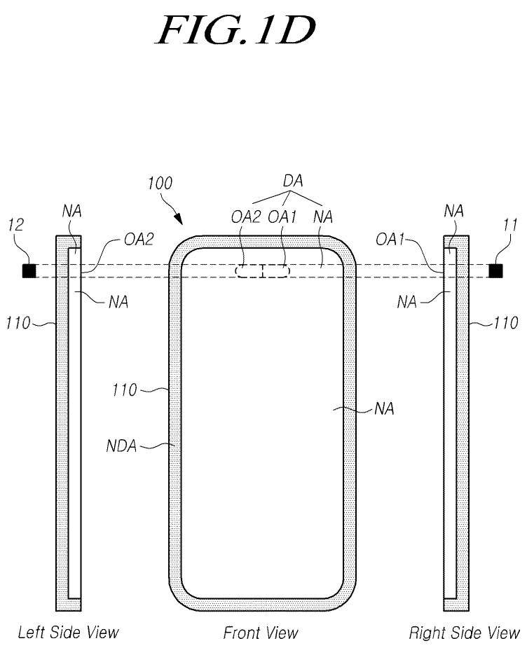

FIGS. 1A, 1B, 1C, and 1D are plan diagrams illustrating a display device 100 according to embodiments of the present disclosure;

Referring to FIGS. 1A to 1D, the display device 100 according to embodiments of the present disclosure may include a display panel 110 to display an image and one or more optoelectronic devices 11 and 12.

The display panel 110 may include a display area DA on which images are displayed and a non-display area NDA on which no images are displayed.

On the display area DA, a plurality of subpixels and a variety of signal lines for driving the plurality of subpixels may be disposed.

The non-display area NDA may be an area outside the display area DA. On the non-display area NDA, a variety of signal lines may be disposed and a variety of driver circuits may be connected. The non-display area NDA may be bent so as not to be seen from the front or covered with a housing (not shown). The non-display area NDA is also referred to as a bezel or a second bezel area. This is a second bezel area that is different from the first bezel area that is located in the optical area and is in the display area. All or a portion of the non-display area NDA may be an area visible from the front surface of the display device 100, or an area that is bent and invisible from the front surface of the display device 100.

Referring to FIGS. 1A to 1D, in the display device 100 according to embodiments of the present disclosure, the one or more optoelectronic devices 11 and 12 are electronic components located below (i.e., on a side opposite to the viewing side of) the display panel 110.

Light may enter the display panel 110 through the front side (i.e., the viewing side), pass through the display panel 110, and reach the one or more optoelectronic devices 11 and 12 located below (i.e., on the side opposite to the viewing side of) the display panel 110.

The one or more optoelectronic devices 11 and 12 may be devices respectively receiving light that has passed through the display panel 110 and performing a predetermined function in response to the received light. For example, the one or more optoelectronic devices 11 and 12 may include at least one among image-capturing devices such as a camera (or an image sensor) and sensors such as a proximity sensor and a light sensor.

Referring to FIGS. 1A to 1D, in the display panel 110 according to embodiments of the present disclosure, the display area DA may include a normal area NA and one or more optical areas OA1 and OA2.

Referring to FIGS. 1A to 1D, each of the one or more optical areas OA1 and OA2 may be an area overlapping at least one of the one or more optoelectronic devices 11 and 12.

According to the illustration of FIG. 1A, the display area DA may include the normal area NA and the first optical area OA1. At least a portion of the first optical area OA1 may overlap the first optoelectronic device 11.

The first optical area OA1 having a circular structure is illustrated in FIG. 1A, but the shape of the first optical area OA1 according to embodiments of the present disclosure is not limited thereto.

For example, as illustrated in FIG. 1B, the first optical area OA1 may have an octagonal shape, and may also have any one of a variety of other polygonal shapes.

According to the illustration of FIG. 1C, the display area DA may include the normal area NA, the first optical area OA1, and the second optical area OA2. In the illustration of FIG. 1C, the normal area NA is present between the first optical area OA1 and the second optical area OA2. At least a portion of the first optical area OA1 may overlap the first optoelectronic device 11, and at least a portion of the second optical area OA2 may overlap the second optoelectronic device 12.

According to the illustration of FIG. 1D, the display area DA may include the normal area NA, the first optical area OA1, and the second optical area OA2. In the illustration of FIG. 1D, the normal area NA is not present between the first optical area OA1 and the second optical area OA2. That is, the first optical area OA1 and the second optical area OA2 are in contact with each other. At least a portion of the first optical area OA1 may overlap the first optoelectronic device 11, and at least a portion of the second optical area OA2 may overlap the second optoelectronic device 12.

The one or more optical areas OA1 and OA2 are required to have both an image-displaying structure and a light-transmitting structure. That is, since one or more optical areas OA1 and OA2 are portions of the display area DA, subpixels for displaying images should be disposed in the one or more optical areas OA1 and OA2. In addition, a light-transmitting structure should be disposed in the one or more optical areas OA1 and OA2 to transmit light to the one or more optoelectronic devices 11 and 12.

The one or more optoelectronic devices 11 and 12 are required to receive light and are located behind (or below, i.e., on the side opposite to the viewing side of) the display panel 110 to receive light that has passed through the display panel 110.

None of the one or more optoelectronic devices 11 and 12 is exposed through the front side (i.e., the viewing side) of the display panel 110. Thus, when a user views the front side of the display device 100, none of the one or more optoelectronic devices 11 and 12 is visible to the user.

For example, the first optoelectronic device 11 may be a camera, whereas the second optoelectronic device 12 may be a sensor such as a proximity sensor or a light sensor. For example, the sensor may be an infrared (IR) sensor that detects IR radiation.

In contrast, the first optoelectronic device 11 may be a sensor, whereas the second optoelectronic device 12 may be a camera.

Hereinafter, for the sake of brevity, the first optoelectronic device 11 will be illustrated as being a camera, whereas the second optoelectronic device 12 will be illustrated as being a sensor. The camera may be a camera lens or an image sensor.

When the first optoelectronic device 11 is a camera, the camera may be a front camera located behind (or below) the display panel 110 to capture images in a front-facing direction. Thus, the user may capture images using the camera not visible through the viewing side of the display panel 110 while viewing the viewing side.

Even in the case that the normal area NA and the one or more optical areas OA1 and OA2 of the display area DA are areas on which images may be displayed, the normal area NA is an area in which the light-transmitting structure is not required to be provided, while the one or more optical areas OA1 and OA2 are areas in which the light-transmitting structure is required to be provided.

Thus, the one or more optical areas OA1 and OA2 are required to have a predetermined level of transmittance or higher, while the normal area NA may entirely lack light transmittance or may have light transmittance lower than the predetermined level.

For example, at least one of resolution, a subpixel arrangement structure, a number of subpixels per area, an electrode structure, a line structure, an electrode arrangement structure, a line arrangement structure, or the like in the one or more optical areas OA1 and OA2 may be different from a corresponding one thereof in the normal area NA.

For example, the number of subpixels per area in the one or more optical areas OA1 and OA2 may be lower than the number of subpixels per area in the normal area NA. That is, the resolution of the one or more optical areas OA1 and OA2 may be lower than the resolution of the normal area NA. Here, the number of subpixels per area may be the unit of measurement of resolution and also be referred to as pixels per inch (PPI) indicating the number of pixels in a one inch square (1 in²).

For example, the number of subpixels per area in the first optical area OA1 may be lower than the number of subpixels per area in the normal area NA. The number of subpixels per area in a (1-2)th optical area OA1OA2 may be equal to or greater than the number of subpixels per area in a (2-1)th optical area OA2OA1.

The first optical area OA1 may have any one of a variety of shapes such as a circle, an ellipse, a quadrangle, a hexagon, or an octagon. The second optical area OA2 may have any one of a variety of shapes such as a circle, an ellipse, a quadrangle, a hexagon, or an octagon. The first optical area OA1 and the second optical area OA2 may have the same shape or different shapes.

Referring to FIG. 1C, when the first optical area OA1 and the second optical area OA2 are in contact with each other, the entire optical area including the first optical area OA1 and the second optical area OA2 may have any one of a variety of shapes such as a circle, an ellipse, a quadrangle, a hexagon, or an octagon.

Hereinafter, for the sake of brevity, each of the first optical area OA1 and the second optical area OA2 will be illustrated as being circular.

In the display device 100 according to embodiments of the present disclosure, when the first optoelectronic device 11 covered below the device panel 110 so as not to be exposed externally is a camera, the display device 100 according to embodiments of the present disclosure may be a display to which under-display camera (UDC) technology is applied.

With this configuration, in the display device 100 according to embodiments of the present disclosure, the display panel 110 is not required to be provided with a notch or a camera hole through which a camera is exposed. Thus, the area size of the display area DA is not reduced.

Accordingly, since there is no need for the display panel 110 to be provided with a notch or a camera hole through which a camera is exposed, the size of the bezel area may be reduced, and a design limiting factor may also be removed, thereby increasing a degree of design freedom.

In the display device 100 according to embodiments of the present disclosure, even in the case that the one or more optoelectronic devices 11 and 12 are located to be hidden behind the display panel 110, one or more optoelectronic devices 11 and 12 are required to be able to normally receive light and normally perform the predetermined function.

In addition, in the display device 100 according to embodiments of the present disclosure, even in the case that the one or more optoelectronic devices 11 and 12 are located to be hidden behind the display panel 110 and overlap the display area DA, the one or more optical areas OA1 and OA2 of the display area DA overlapping the one or more optoelectronic devices 11 and 12 are required to be able to normally display images.

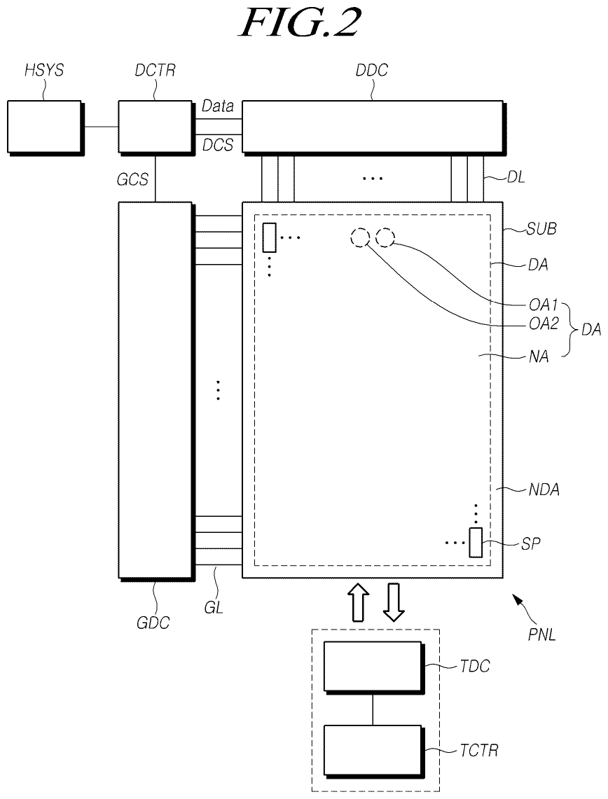

FIG. 2 is a diagram illustrating a system configuration of the display device 100 according to embodiments of the present disclosure.

Referring to FIG. 2, the display device 100 may include a display panel PNL and a display driver circuit as components for displaying images. The display panel PNL may correspond to the display panel 110 illustrated in FIGS. 1A to 1D.

The display driver circuit is a circuit for driving the display panel PNL, and may include a data driver circuit DDC, a gate driver circuit GDC, a display controller DCTR, and the like.

The display panel PNL may include a display area DA on which images are displayed and a non-display area NDA on which no images are displayed. The non-display area NDA may be an area outside the display area DA, and may also be referred to as a bezel area. The entirety or a portion of the non-display area NDA may be an area visible through the front side of the display device 100 or be bent so as not to be visible through the front side of the display device 100.

The display panel PNL may include a substrate SUB and a plurality of subpixels SP disposed on the substrate SUB. In addition, the display panel PNL may further include various types of signal lines in order to drive the plurality of subpixels SP.

The display device 100 according to embodiments of the present disclosure may be a liquid crystal display (LCD) or a self-luminous display device in which the display panel PNL or the like emits light by itself. When the display device 100 according to embodiments of the present disclosure is a self-luminous display device, each of the plurality of subpixels SP may include a light-emitting device.

For example, the display device 100 according to embodiments of the present disclosure may be an organic light-emitting display device of which light-emitting devices are implemented as organic light-emitting diodes (OLEDs). In another example, the display device 100 according to embodiments of the present disclosure may be an inorganic light-emitting display device of which light-emitting devices are implemented as inorganic light-emitting diodes. In another example, the display device 100 according to embodiments of the present disclosure may be a quantum dot display device of which light-emitting devices are implemented as quantum dots (QDs) that are self-luminous semiconductor crystals.

The structure of each of the plurality of subpixels SP may vary depending on the type of the display device 100. For example, when the subpixels SP of the display device 100 are self-luminous display devices, each of the subpixels SP may include a self-luminous element, one or more transistors, and one or more capacitors.

For example, various types of signal lines may include a plurality of data lines DL through which data signals (also referred to as data voltages or image signals) are transmitted, gate lines GL through which gate signals (also referred to as scanning signals) are transmitted, and the like.

The plurality of data lines DL may intersect the plurality of gate lines GL. Each of the plurality of data lines DL may be disposed to extend in a first direction. Each of the plurality of gate lines GL may be disposed to extend in a second direction.

Here, the first direction may be a column direction, whereas the second direction may be a row direction. Alternatively, the first direction may be a row direction, whereas the second direction may be a column direction.

The data driver circuit DDC is a circuit for driving the plurality of data lines DL, and may output data signals to the plurality of data lines DL. The gate driver circuit GDC is a circuit for driving the plurality of gate lines GL, and may output gate signals to the plurality of gate lines GL.

The display controller DCTR is a device for controlling the data driver circuit DDC and the gate driver circuit GDC, and may control driving points in time regarding the plurality of data lines DL and driving points in time regarding the plurality of gate lines GL.

The display controller DCTR may transfer a data drive control signal (DCS) to the data driver circuit DDC to control the data driver circuit DDC and a gate drive control signal (GCS) to the gate driver circuit GDC to control the gate driver circuit GDC.

The display controller DCTR may receive input image data from a host system HSYS and transfer image data Data based on the input image data to the data driver circuit DDC.

The data driver circuit DDC may transfer data signals to the plurality of data lines DL in response to drive timing control of the display controller DCTR.

The data driver circuit DDC may receive the digital image data Data from the display controller DCTR, convert the received image data Data into analog data signals, and output the analog data signals to the plurality of data lines DL.

The gate driver circuit GDC may transfer gate signals to the plurality of gate lines GL in response to timing control of the display controller DCTR. The gate driver circuit GDC may receive a first gate voltage corresponding to a turn-on level voltage and a second gate voltage corresponding to a turn-off level voltage together with a variety of gate drive control signals GCS to generate gate signals and transfer the generated gate signals to the plurality of gate lines GL.

For example, the data driver circuit DDC may be connected to the display panel PNL by a tape-automated bonding (TAB) method, connected to a bonding pad of the display panel PNL by a chip-on-glass (COG) method or a chip-on-panel (COP) method, or implemented and connected to the display panel PNL by a chip-on-film (COF) method.

The gate driver circuit GDC may be connected to the display panel PNL by a TAB method, connected to a bonding pad of the display panel PNL by a COG method or a COP method, or connected to the display panel PNL by COF method. Alternatively, the gate driver circuit GDC may be formed on the non-display area NDA of the display panel PNL by a gate-in-panel (GIP) method. The gate driver circuit GDC may be disposed on or connected to a substrate. That is, when the gate driver circuit GDC is a GIP-type gate driver circuit, the gate driver circuit GDC may be disposed on the non-display area NDA. When the gate driver circuit GDC is formed by a COG-type gate driver circuit or a COF-type gate driver circuit, the gate driver circuit GDC may be connected to the substrate.

In addition, at least one driver circuit of the data driver circuit DDC and the gate driver circuit GDC may be disposed on the display area DA of the display panel PNL. For example, at least one driver circuit of the data driver circuit DDC and the gate driver circuit GDC may be disposed so as not to overlap the subpixels SP or may be disposed to overlap a portion of or the entirety of the subpixels SP.

The data driver circuit DDC may be connected to one side (e.g., the upper side or the lower side) of the display panel PNL. The data driver circuit DDC may be connected to both sides (e.g., both the upper side and the lower side) or connected to two or more sides of four sides of the display panel PNL, depending on the driving method, the design of the display panel, or the like.

The gate driver circuit GDC may be connected to one side (e.g., the left side or the right side) of the display panel PNL. The gate driver circuit GDC may be connected to both sides (e.g., both the left side and the right side) of the display panel PNL or connected to two or more sides of four sides of the display panel PNL, depending on the driving method, the design of the display panel, or the like.

The display controller DCTR be implemented as a separate component together with the data driver circuit DDC, or may be integrated with the data driver circuit DDC into an integrated circuit (IC).

The display controller DCTR may be a timing controller used in typical display technology, a control device including a timing controller and able to perform other control functions, a control device different from the timing controller, or a circuit in a control device. The display controller DCTR may be implemented as any one of a variety of circuits or electronic components such as an integrated circuit (IC), a field programmable gate array (FPGA), an application specific integrated circuit (ASIC), or a processor.

The display controller DCTR may be mounted on a printed circuit board (PCB), a flexible printed circuit (FPC), or the like and electrically connected to the data driver circuit DDC and the gate driver circuit GDC through the PCB, the FPC, or the like.

The display controller DCTR may transmit and receive signals to and from the data driver circuit DDC according to predetermined one or more interfaces. For example, examples of the interface may include a low voltage differential signaling (LVDS) interface, an embedded clock point-to-point interface (EPI), a serial peripheral interface (SPI), and the like.

The display device 100 according to embodiments of the present disclosure may include a touch sensor and a touch sensing circuit detecting the occurrence of a touch performed by a touch object, such as a finger or a pen, or determining a touch position by sensing the touch sensor.

The touch sensing circuit may include a touch driver circuit TDC generating and outputting touch sensing data by driving and sensing the touch sensor, a touch controller TCTR able to detect the occurrence of a touch and determining a touch position, and the like.

The touch sensor may include a plurality of touch electrodes. The touch sensor may further include a plurality of touch lines for electrically connecting the plurality of touch electrodes and the touch driver circuit TDC.

The touch sensor may be present outside the display panel PNL as a touch panel or present inside the display panel PNL. In the case that the touch sensor is present outside the display panel PNL as a touch panel, the touch sensor is referred to as an add-on touch sensor. In the case that the touch sensor is an add-on touch sensor, the touch panel and the display panel PNL may be fabricated separately and fitted to each other in an assembly process. The add-on touch panel may include a substrate for a touch panel, a plurality of touch electrodes on the substrate for a touch panel, and the like.

When the touch sensor is present inside the display panel PNL, the touch sensor may be formed on the substrate SUB together with signal lines and electrodes related to display driving during the fabrication process of the display panel PNL.

The touch driver circuit TDC may transfer a touch driving signal to at least one of the plurality of touch electrodes and generate touch sensing data by sensing at least one of the plurality of touch electrodes.

The touch sensing circuit may perform touch sensing by a self-capacitance sensing method or a mutual-capacitance sensing method.

When the touch sensing circuit performs touch sensing using the self-capacitance sensing method, the touch sensing circuit may perform touch sensing on the basis of the capacitance between each touch electrode and a touch object (e.g., a finger, a pen, etc.).

According to the self-capacitance sensing method, each of the plurality of touch electrodes may serve as both a drive touch electrode and a sensing touch electrode. The touch driver circuit TDC may drive the entirety of or a portion of the plurality of touch electrodes and sense the entirety or a portion of the plurality of touch electrodes.

When the touch sensing circuit performs touch sensing using the mutual-capacitance sensing method, the touch sensing circuit may perform touch sensing on the basis of capacitance between touch electrodes.

According to the mutual-capacitance sensing method, the plurality of touch electrodes are divided into driving touch electrodes and sensing touch electrodes. The touch driver circuit TDC may drive the driving touch electrodes and sense the sensing touch electrodes.

The touch driver circuit TDC and the touch controller TCTR in the touch sensing circuit may be implemented as separate devices or a single device. In addition, the touch driver circuit TDC and the data driver circuit DDC may be implemented as separate devices or a single device.

The display device 100 may include a power supply circuit or the like supplying various types of power to at least one of the display driver circuit and touch sensing circuit.

The display device 100 according to embodiments of the present disclosure may be a mobile device, such as a smart phone or a tablet, or a monitor, a TV, or the like, having a variety of sizes. However, the display device 100 is not limited thereto, and may be various types of display devices having a variety of sizes able to display information or images.

As described above, the display area DA in the display panel PNL may include the normal area NA and the one or more optical areas OA1 and OA2.

The normal area NA and the one or more optical areas OA1 and OA2 are areas on which images may be displayed. However, the normal area NA is an area in which the light-transmitting structure is not required to be formed, whereas the one or more optical areas OA1 and OA2 are areas in which the light-transmitting structure is required to be formed.

As described above, the display area DA in the display panel PNL may include the one or more optical areas OA1 and OA2 in addition to the normal area NA. For the sake of brevity, the display area DA will be taken to include both the first optical area OA1 and second optical area OA2 (see FIGS. 1B and 1C).

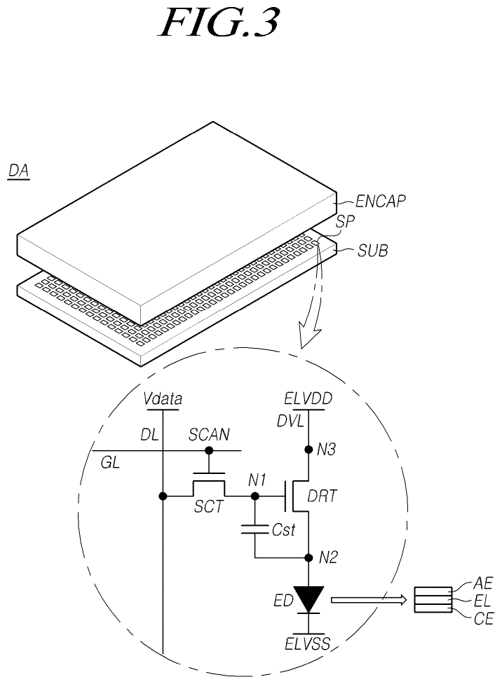

FIG. 3 is an equivalent circuit diagram of each of the subpixels SP in the display panel PNL according to embodiments of the present disclosure.

Each of the subpixels SP disposed in the normal area NA, the first optical area OA1, and the second optical area OA2 included in the display area DA of the display panel PNL may include: an emitting device ED; a driving transistor DRT driving the emitting device ED; a scanning transistor SCT transferring a data voltage VDATA to a first node N1 of the driving transistor DRT; a storage capacitor Cst maintaining a predetermined voltage for a single-frame time.

The driving transistor DRT may include: the first node N1 to which a data voltage is applicable; a second node N2 electrically connected to the emitting device ED; and a third node N3 to which a driving voltage ELVDD from a driving voltage line DVL is applied. In the driving transistor DRT, the first node N1 may be a gate node, the second node N2 may be a source node or a drain node, and the third node N3 may be a drain node or a source node.

The emitting device ED may include an anode AE, an emitting layer EL, and a cathode CE. The anode AE may be a pixel electrode disposed in each of the subpixels SP and electrically connected to the second node N2 of the driving transistor DRT of each of the subpixels SP. The cathode CE may be a common electrode disposed in common to the plurality of subpixels SP, and a base voltage ELVSS may be applied to the cathode CE.

For example, the anode AE may be a pixel electrode, and the cathode CE may be a common electrode. In contrast, the anode AE may be a common electrode, whereas the cathode CE may be a pixel electrode. Hereinafter, for the sake of brevity, the anode AE will be supposed to be a pixel electrode, whereas the cathode CE will be supposed to be a common electrode.

For example, the emitting device ED may be an OLED, an inorganic light-emitting diode, a quantum dot element, or the like. In this case, when the emitting device ED is an OLED, the emitting layer EL of the emitting device ED may include an organic emitting layer containing an organic material.

The scanning transistor SCT may be on/off controlled by a scanning signal SCAN, i.e., a gate signal, applied through a gate line GL. The scanning transistor SCT may be electrically connected to the first node N1 of the driving transistor DRT and a data line DL.

The storage capacitor Cst may be electrically connected to the first node N1 and the second node N2 of the driving transistor DRT.

As illustrated in FIG. 3, each of the subpixels SP may have a 2-transistor 1-capacitor (2T1C) structure including two transistors DRT and SCT and a single capacitor Cst. In some cases, each of the subpixels SP may further include one or more transistors or one or more capacitors.

The storage capacitor Cst may be an external capacitor intentionally designed to be provided externally of the driving transistor DRT, rather than a parasitic capacitor (e.g., Cgs or Cgd), i.e., an internal capacitor that may be present between the first node N1 and the second node N2 of the driving transistor DRT.

Each of the driving transistor DRT and the scanning transistor SCT may be an N-type transistor or a P-type transistor.

Since circuit elements (in particular, the emitting device ED) in each of the subpixels SP is vulnerable to external moisture, oxygen, or the like, an encapsulation layer ENCAP may be disposed on the display panel PNL to prevent external moisture or oxygen from penetrating into the circuit elements (in particular, the emitting device ED). The encapsulation layer ENCAP may be disposed to cover the emitting devices ED.

In addition, as a method for increasing the transmittance of at least one of the first optical area OA1 and the second optical area OA2, a differential pixel density design method as described above may be used. According to the differential pixel density design method, the display panel PNL may be designed such that the number of subpixels per area of at least one of the first optical area OA1 and the second optical area OA2 is greater than the number of subpixels per area of the normal area NA.

However, in some cases, differently, as another method for increasing the transmittance of at least one of the first optical area OA1 and the second optical area OA2, a pixel size differential design method may be used. According to the pixel size differential design method, the display panel PNL may be designed such that the number of subpixels per area of at least one of the first optical area OA1 and the second optical area OA2 is the same as or similar to the number of subpixels per area of the normal area NA and the size of each of the subpixels SP (i.e., the size of an emitting area) is smaller than the size (i.e., the size of the emitting area) of each of the subpixels SP disposed in the normal area NA.

Hereinafter, for the sake of brevity, it will be described by assuming that the differential pixel density design method of the two methods (i.e., the differential pixel density design method and the pixel size differential design method) for increasing the transmittance of at least one of the first optical area OA1 and the second optical area OA2 is used.

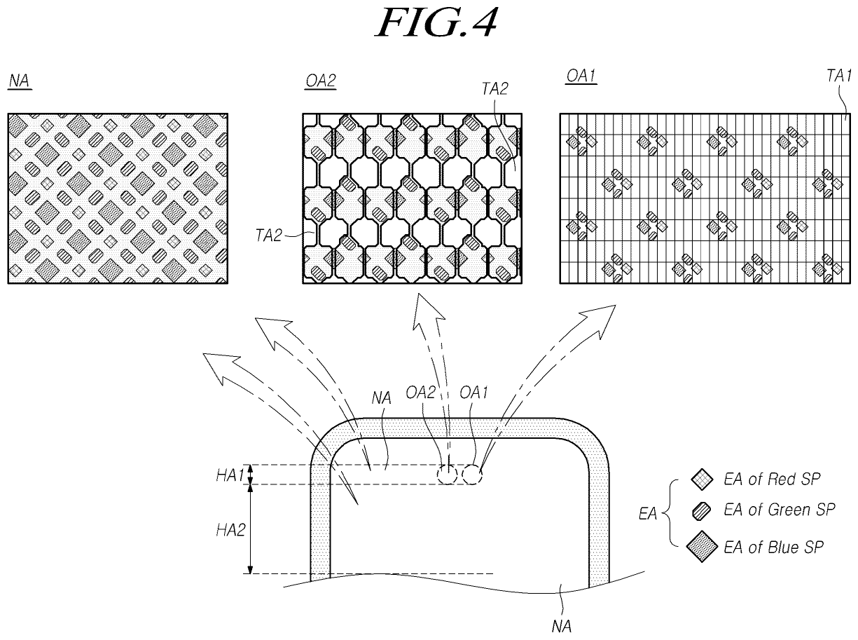

FIG. 4 is a layout diagram of subpixels in the three areas NA, OA1, and OA2 in the display area DA of the display panel PNL according to embodiments of the present disclosure.

Referring to FIG. 4, a plurality of subpixels SP may be disposed in each of the normal area NA, the first optical area OA1, and the second optical area OA2 of the display area DA.

For example, the plurality of subpixels SP may include may include red subpixels Red SP emitting red light, green subpixels Green SP emitting green light, and blue subpixels Blue SP emitting blue light.

Accordingly, each of the normal area NA, the first optical area OA1, and the second optical area OA2 may include emitting areas EA of the red subpixels Red SP, emitting areas EA of the green subpixels Green SP, and emitting areas EA of the blue subpixels Blue SP.

Referring to FIG. 4, the normal area NA may include emitting areas EA without including the light-transmitting structure.

However, each of the first optical area OA1 and the second optical area OA2 is required to include not only the emitting areas EA but also the light-transmitting structure.

Thus, the first optical area OA1 may include the emitting areas EA and first transmission areas TA1, whereas the second optical area OA2 may include the emitting areas EA and second transmission areas TA2.

The emitting areas EA and the transmission areas TA1 and TA2 may be distinguished depending on whether or not light transmission is possible. The transmission areas TA1 and TA2 may be areas allowing light to pass therethrough.

In addition, the emitting areas EA and the transmission areas TA1 and TA2 may be distinguished depending on whether or not a specific metal layer CE is formed. For example, the emitting areas EA may be provided with the cathode CE, whereas none of the transmission areas TA1 and TA2 may be provided with the cathode CE. The emitting areas EA may be provided with a light shield layer, whereas none of the transmission areas TA1 and TA2 may be provided with a light shield layer.

Since the first optical area OA1 includes the first transmission areas TA1 and the second optical area OA2 includes the second transmission areas TA2, both the first optical area OA1 and the second optical area OA2 are areas allowing light to pass therethrough.

The transmittance (or the degree of transmission) of the first optical area OA1 and the transmittance (or the degree of transmission) of the second optical area OA2 may be the same.

In this case, the shape or size of the first transmission areas TA1 of the first optical area OA1 may be the same as the shape or size of the second transmission areas TA2 of the second optical area OA2. Even in the case that the shape or size of the first transmission areas TA1 of the first optical area OA1 is different from the shape or size of the second transmission areas TA2 of the second optical area OA2, the ratio of the first transmission areas TA1 with respect to the first optical area OA1 may be the same as the ratio of the second transmission areas TA2 with respect to the second optical area OA2.

Alternatively, the transmittance (or the degree of transmission) of the first optical area OA1 is different from the transmittance (or the degree of transmission) of the second optical area OA2.

In this case, the shape or size of the first transmission areas TA1 of the first optical area OA1 may be different from the shape or size of the second transmission areas TA2 of the second optical area OA2. Even in the case that the shape or size of the first transmission areas TA1 of the first optical area OA1 is the same as the shape or size of the second transmission areas TA2 of the second optical area OA2, the ratio of the first transmission areas TA1 with respect to the first optical area OA1 may be different from the ratio of the second transmission areas TA2 with respect to the second optical area OA2.

For example, when the first optoelectronic device 11 overlapping the first optical area OA1 is a camera and the second optoelectronic device 12 overlapping the second optical area OA2 is a sensor, the camera may need a greater amount of light than the sensor.

Thus, the transmittance (or the degree of transmission) of the first optical area OA1 may be higher than the transmittance (or the degree of transmission) of the second optical area OA2.

In this case, the size of the first transmission areas TA1 in the first optical area OA1 may be greater than the size of the second transmission areas TA2 in the second optical area OA2. Even in the case that the size of the first transmission areas TA1 in the first optical area OA1 is the same as the size of the second transmission areas TA2 in the second optical area OA2, the ratio of the first transmission areas TA1 with respect to the first optical area OA1 may be greater than the ratio of the second transmission areas TA2 with respect to the second optical area OA2.

Hereinafter, for the sake of brevity, a case in which the transmittance (or the degree of transmission) of the first optical area OA1 is higher than the transmittance (or the degree of transmission) of the second optical area OA2 will be described as an example.

In addition, as illustrated in FIG. 4, in embodiments of the present disclosure, the transmission areas TA1 and TA2 may also be referred to as transparent areas, and the transmittance may also be referred to as transparency.

In addition, as illustrated in FIG. 4, in embodiments of the present disclosure, a case in which the first optical area OA1 and the second optical area OA2 are located in the top portion of the display area DA of the display panel PNL and disposed side by side will be described.

Referring to FIG. 4, a horizontal display area in which the first optical area OA1 and the second optical area OA2 are disposed will be referred to as a first horizontal display area HAL and a horizontal display area in which none of the first optical area OA1 and the second optical area OA2 are disposed will be referred to as a second horizontal display area HA2.

Referring to FIG. 4, the first horizontal display area HA1 may include a portion of the normal area NA, the first optical area OA1, and the second optical area OA2. The second horizontal display area HA2 may only include a portion of the normal area NA.

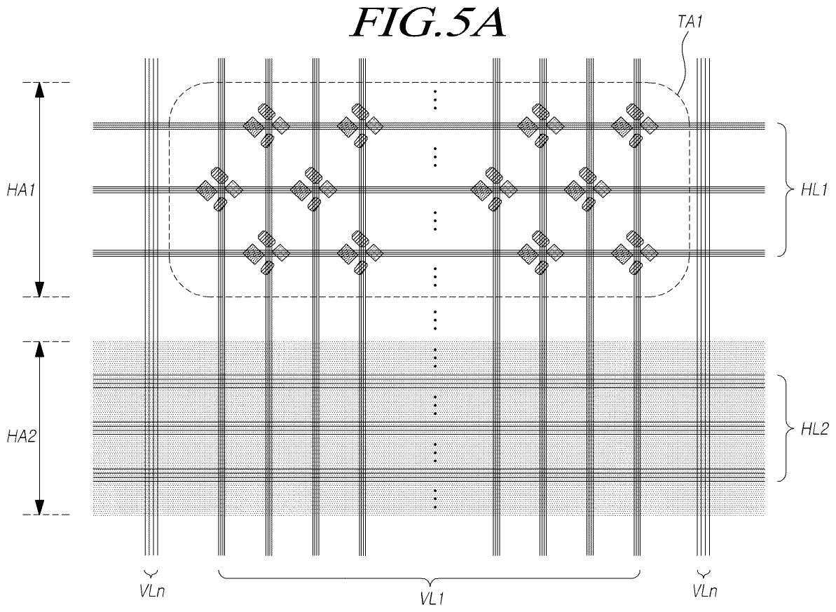

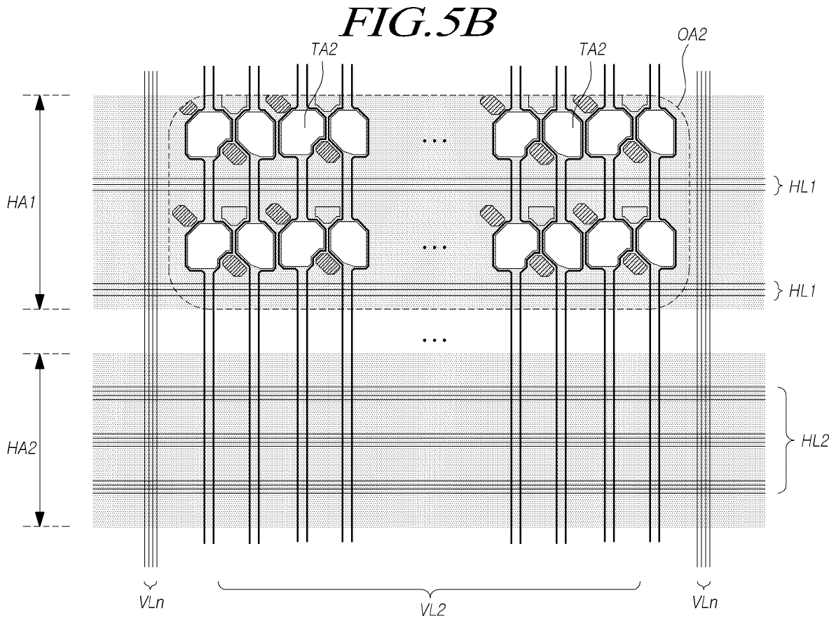

FIG. 5A is a layout diagram of signal lines in the first optical area OA1 and the normal area NA in the display panel PNL according to embodiments of the present disclosure, while FIG. 5B is a layout diagram of signal lines in the second optical area OA2 and the normal area NA in the display panel PNL according to embodiments of the present disclosure.

The first horizontal display area HA1 illustrated in FIGS. 5A and 5B is a portion of the first horizontal display area HA1 in the display panel PNL, whereas the second horizontal display area HA2 is a portion of the second horizontal display area HA2 in display panel PNL.

The first optical area OA1 illustrated in FIG. 5A is a portion of the first optical area OA1 in the display panel PNL, whereas the second optical area OA2 illustrated in FIG. 5B is a portion of the second optical area OA2 in the display panel PNL.

Referring to FIGS. 5A and 5B, the first horizontal display area HA1 may include a portion of the normal area NA, the first optical area OA1, and the second optical area OA2. The second horizontal display area HA2 may include a portion of the normal area NA.

Various types of horizontal lines HL1 and HL2 and various types of vertical lines VLn, VL1, and VL2 may be disposed in the display panel 110.

In embodiments of the present disclosure, the horizontal direction and the vertical direction refer to two intersecting directions. The horizontal direction and the vertical direction may vary depending on the viewing direction. For example, the horizontal direction indicates a direction in which a single gate line GL is disposed and extends, wherein the vertical direction indicates a direction in which a single data line DL is disposed and extends. In this manner, the horizontal direction and the vertical direction will be taken as an example.

Referring to FIGS. 5A and 5B, the horizontal lines disposed in the display panel PNL may include first horizontal lines HL1 disposed in the first horizontal display area HA1 and the second horizontal lines HL2 disposed in the second horizontal display area HA2.

The horizontal lines disposed in the display panel PNL may be gate lines GL. That is, the first horizontal lines HL1 and the second horizontal lines HL2 may be gate lines GL. The gate lines GL may include various types of gate lines depending on the structure of the subpixels SP.

Referring to FIGS. 5A and 5B, the vertical lines disposed in the display panel PNL may include normal vertical lines VLn only disposed in the normal area NA, first vertical lines VL1 extending through both the second optical area OA2, the normal area NA, and second vertical lines VL2 extending through both the second optical area OA2 and the normal area NA.

The vertical lines disposed in the display panel PNL may include data lines DL, driving voltage lines DVL, or the like, and may also include reference voltage lines, initialization voltage lines, or the like. That is, the normal vertical lines VLn, the first vertical lines VL1, and the second vertical lines VL2 may include the data lines DL, the driving voltage lines DVL, or the like, and may also include the reference voltage lines, the initialization voltage lines, or the like.

In embodiments of the present disclosure, the term “horizontal” in the second horizontal line HL2 only indicates that a signal is transmitted from the left to the right (or from the right to the left), but does not indicate that the second horizontal line HL2 only extends linearly in a horizontal direction. That is, the second horizontal line HL2 is illustrated in the form of a straight line in FIGS. 5A and 5B, but may include bent or curved portions. In the same manner, the first horizontal line HL1 may include bent or curved portions.

In embodiments of the present disclosure, the term “vertical” in the normal vertical line VLn only indicates that a signal is transmitted from the upper side to the lower side (or from the lower side to the upper side), but does not indicate that the normal vertical line VLn only extends linearly in a vertical direction. That is, the normal vertical line VLn is illustrated in the form of a straight line in FIGS. 5A and 5B, but may include bent or curved portions. In the same manner, the first vertical line VL1 and the second vertical line VL2 may include bent or curved portions.

Referring to FIG. 5A, the first optical area OA1 included in the first horizontal display area HA1 may include the emitting areas EA and the first transmission areas TA1. In the first optical area OA1, an outer area of the first transmission areas TA1 may include the emitting areas EA.

Referring to FIG. 5A, in order to improve the transmittance of the first optical area OA1, the first horizontal lines HL1 passing through the first optical area OA1 may bypass the first transmission areas TA1 in the first optical area OA1.

Thus, each of the first horizontal lines HL1 passing through the first optical area OA1 may include a curved section or a bent section bypassing the boundaries of the first transmission areas TA1.

Thus, the shape, the length, or the like of the first horizontal line HL1 disposed in the first horizontal display area HA1 may be different from the shape, the length, or the like of the second horizontal line HL2 disposed in the second horizontal display area HA2. That is, the shape, the length, or the like of the first horizontal line HL1 passing through the first optical area OA1 may be different from the shape, the length, or the like of the second horizontal line HL2 not passing through the first optical area OA1.

In addition, in order to improve the transmittance of the first optical area OA1, the first vertical lines VL1 passing through the first optical area OA1 may bypass the first transmission areas TA1 in the first optical area OA1.

Thus, each of the first vertical lines VL1 passing through the first optical area OA1 may include a curved section, a bent section, or the like. bypassing the boundary of each of the first transmission areas TA1.

Accordingly, the shape, the length, or the like of the first vertical line VL1 passing through the first optical area OA1 may be different from the shape, the length, or the like of the normal vertical line VLn disposed in the normal area NA without passing through the first optical area OA1.

Referring to FIG. 5A, the first transmission areas TA1 included in the first optical area OA1 in the first horizontal display area HA1 may be disposed in oblique directions (or in a staggered arrangement).

Referring to FIG. 5A, in the first optical area OA1 in the first horizontal display area HAL emitting areas EA may be disposed between two first transmission areas TA1 adjacent to each other in the transverse direction. In the first optical area OA1 in the first horizontal display area HAL emitting areas EA may be disposed between two first transmission areas TA1 adjacent to each other in the top-bottom direction.

Referring to FIG. 5A, each of the first horizontal lines HL1 disposed in the first horizontal display area HAL i.e., passing through the first optical area OA1, may include at least one of curved sections or bent sections bypassing the boundaries of the first transmission areas TA1.

Referring to FIG. 5B, the second optical area OA2 included in the first horizontal display area HA1 may include the emitting areas EA and the second transmission areas TA2. In the second optical area OA2, outer areas of the second transmission areas TA2 may include the emitting areas EA.

Positions and arrangement states of the emitting areas EA and the second transmission areas TA2 in the second optical area OA2 may be the same as positions and arrangement states of the emitting areas EA and the second transmission areas TA2 in the first optical area OA1 illustrated in FIG. 5A.

Alternatively, as illustrated in FIG. 5B, the positions and arrangement states of the emitting areas EA and the second transmission areas TA2 in the second optical area OA2 may be different from the positions and arrangement states of the emitting areas EA and the second transmission areas TA2 in the first optical area OA1 illustrated in FIG. 5A.

For example, referring to FIG. 5B, in the second optical area OA2, the second transmission areas TA2 may be disposed in the horizontal direction (or the transverse direction). Between two second transmission areas TA2 adjacent in the horizontal direction (or the transverse direction), none of the emitting areas EA may be disposed. In addition, the emitting areas EA in the second optical area OA2 may be disposed between the second transmission areas TA2 adjacent in the vertical direction (or the top-bottom direction). That is, the emitting areas EA may be disposed between two rows of second transmission areas.

When the first horizontal lines HL1 pass through the second optical area OA2 and a portion of the normal area NA adjacent to the second optical area OA2 in the first horizontal display area HAL the first horizontal lines HL1 may extend with the same shape as illustrated in FIG. 5A.

Alternatively, as illustrated in FIG. 5B, when the first horizontal lines HL1 pass through the second optical area OA2 and the portion of the normal area NA adjacent to the second optical area OA2 in the first horizontal display area HAL the first horizontal lines HL1 may extend with a shape different from the shape illustrated in FIG. 5A.

This is because the positions and arrangement states of the emitting areas EA and the second transmission areas TA2 in the second optical area OA2 illustrated in FIG. 5B are different from the positions and arrangement states of the emitting areas EA and the second transmission areas TA2 in the first optical area OA1 illustrated in FIG. 5A.

Referring to FIG. 5B, when the first horizontal lines HL1 pass through the second optical areas OA2 and the portion of the normal area NA adjacent to the second optical area OA2 in the first horizontal display area HAL the first horizontal lines HL1 may extend in the form of straight lines between the second transmission areas TA2 adjacent in the top-bottom direction without a curved section or a bent section.

In other words, a single first horizontal line HL1 may have a curved section or a bent section in the first optical area OA1, but may not have a curved section or a bent section in the second optical area OA2.

In order to improve the transmittance of the second optical area OA2, the second vertical lines VL2 passing through the second optical area OA2 may extend to bypass the second transmission areas TA2 in the second optical area OA2.

Thus, each of the second vertical lines VL2 passing through the second optical area OA2 may include a curved section or a bent section bypassing the boundary of each of the second transmission areas TA2.

Accordingly, the shape, the length, or the like of the second vertical line VL2 passing through the second optical area OA2 may be different from the shape, the length, or the like of the normal vertical line VLn disposed in the normal area NA without passing through the second optical area OA2.

As illustrated in FIG. 5A, the first horizontal line HL1 passing through the first optical area OA1 may have curved sections or bent sections bypassing the boundaries of the first transmission areas TA1.

Thus, the length of the first horizontal line HL1 passing through the first optical area OA1 and the second optical area OA2 may be slightly longer than the length of the second horizontal line HL2 disposed in the normal area NA without passing through the first optical area OA1 or the second optical area OA2.

Accordingly, resistance of the first horizontal line HL1 (hereinafter, also referred to as first resistance) passing through the first optical area OA1 and the second optical area OA2 may be slightly greater than resistance of the second horizontal line HL2 (hereinafter, also referred to as second resistance) only disposed in the normal area NA without passing through the first optical area OA1 or the second optical area OA2.

Referring to FIGS. 5A and 5B, since the first optical area OA1, at least a portion of which overlaps the first optoelectronic device 11, includes a plurality of first transmission areas TA1 and the second optical area OA2, at least a portion of which overlaps the second optoelectronic device 12, includes a plurality of second transmission areas TA2 depending on the light-transmitting structure, the number of subpixels per area of each of the first optical area OA1 and the second optical area OA2 may be lower than the number of subpixels per area of the normal area NA.

The number of subpixels, among the subpixels SP, to which the first horizontal line HL1 passing through the first optical area OA1 and the second optical area OA2 is connected, may be different from the number of subpixels, among the subpixels SP, to which the second horizontal line HL2 only disposed in the normal area NA without passing through the first optical area OA1 or the second optical area OA2 is connected.

The number (i.e., a first number) of subpixels, among the subpixels SP, to which the first horizontal line HL1 passing through the first optical area OA1 and the second optical area OA2 is connected, may be lower than the number (i.e., a second number) of subpixels, among the subpixels SP, to which the second horizontal line HL2 only disposed in the normal area NA without passing through the first optical area OA1 or the second optical area OA2 is connected.

The difference between the first number and the second number may vary depending on the difference between the resolution of each of the first optical area OA1 and the second optical area OA2 and the resolution of the normal area NA. For example, with increases in the difference between the resolution of each of the first optical area OA1 and the second optical area OA2 and the resolution of the normal area NA, the difference between the first number and the second number may increase.

As described above, since the number (i.e., the first number) of subpixels, among the subpixels SP, to which the first horizontal line HL1 passing through the first optical area OA1 and the second optical area OA2 is connected, is lower than the number (i.e., the second number) of subpixels, among the subpixels SP, to which the second horizontal line HL2 only disposed in the normal area NA without passing through the first optical area OA1 or the second optical area OA2 is connected, the area of the first horizontal line HL1 overlapping the surrounding electrodes or lines may be smaller than the area of the second horizontal line HL2 overlapping the surrounding electrodes or lines.

Thus, parasitic capacitance (hereinafter, referred to as first capacitance) generated between the first horizontal line HL1 and the surrounding electrodes or lines may be lower than parasitic capacitance (hereinafter, referred to as second capacitance) generated between the second horizontal line HL2 and the surrounding electrodes or lines.

In consideration of the relative magnitude between the first resistance and the second resistance (first resistance≥second resistance) and the relative magnitude between the first capacitance and the second capacitance (first capacitance«second capacitance), a resistance-capacitance (RC) value (hereinafter, referred to as a first RC value) of the first horizontal line HL1 passing through the first optical area OA1 and the second optical area OA2 may be significantly lower than an RC value (hereinafter, referred to as a second RC value) of the second horizontal line HL2 only disposed in the normal area NA without passing through the first optical area OA1 or the second optical area OA2 (first RC value«second RC value).

Due to the difference (hereinafter, referred to as RC load difference) between the first RC value of the first horizontal line HL1 and the second RC value of the second horizontal line HL2, signal transmission characteristics through the first horizontal line HL1 may be different from signal transmission characteristics through the second horizontal line HL2.

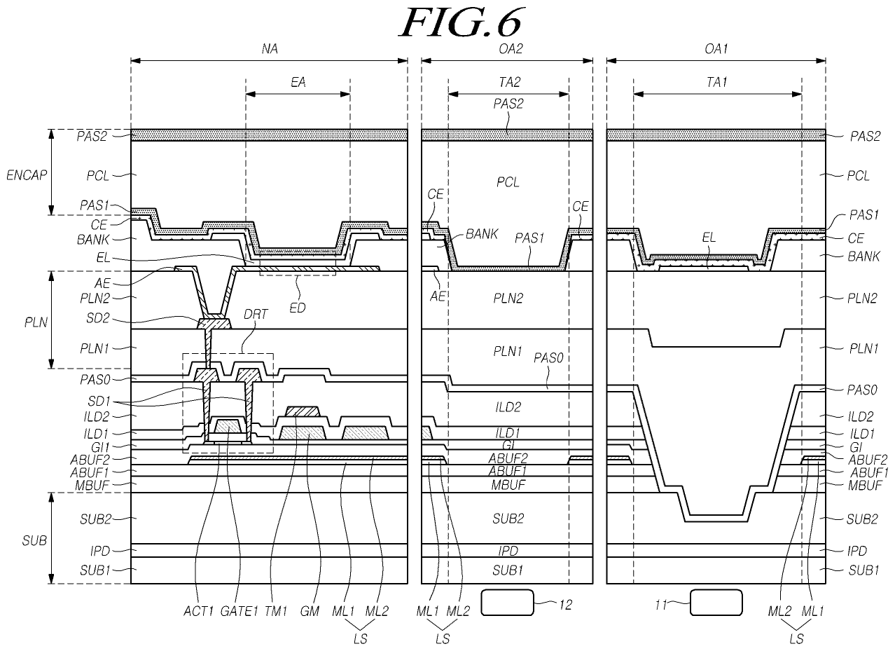

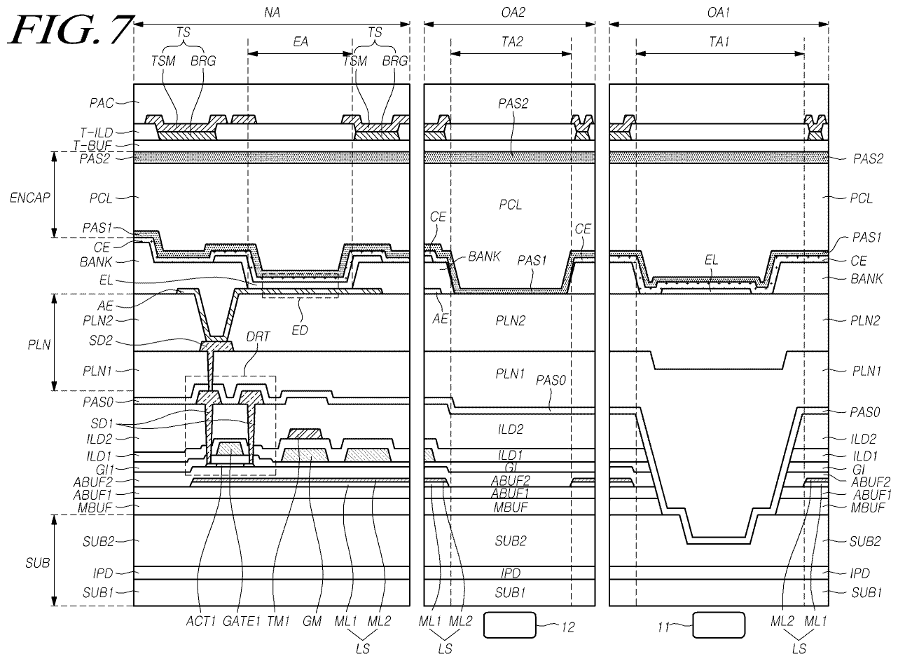

FIGS. 6 and 7 are cross-sectional diagrams of the normal area NA, the first optical area OA1, and the second optical area OA2 included in the display area DA of the display panel PNL according to embodiments of the present disclosure.

FIG. 6 illustrates cross-sections of the display panel PNL in a case in which touch sensors are present outside the display panel PNL in the form of a touch panel, while FIG. 7 illustrates cross-sectional diagrams of the display panel PNL in a case in which touch sensors TS are present inside the display panel PNL.

Each of FIGS. 6 and 7 illustrates cross-sections of the normal area NA, the first optical area OA1, and the second optical area OA2 included in the display area DA.

First, a layered structure of the normal area NA will be described with reference to FIGS. 6 and 7. An emitting area EA included in each of the first optical area OA1 and the second optical area OA2 may have the same layered structure as an emitting area EA included in the normal area NA.

Referring to FIGS. 6 and 7, a substrate SUB may include a first substrate SUB1, an interlayer insulating film IPD, and a second substrate SUB2. The interlayer insulating film IPD may be located between the first substrate SUB1 and the second substrate SUB2. Since the substrate SUB is comprised of the first substrate SUB1, the interlayer insulating film IPD, and the second substrate SUB2, it is possible to prevent moisture penetration. For example, the first substrate SUB1 and the second substrate SUB2 may be polyimide (PI) substrates. The first substrate SUB1 may be referred to as a first PI substrate, while the second substrate SUB2 may be referred to as a second PI substrate.

Referring to FIGS. 6 and 7, a variety of patterns ACT1, SD1, and GATE1 for forming a transistor such as a driving transistor DRT, a variety of insulating films MBUF, ABUF1, ABUF2, GI, ILD1, ILD2, and PAS0, and a variety of metal patterns TM1, GM, ML1, and ML2 may be disposed on the substrate SUB.

Referring to FIGS. 6 and 7, a multi-buffer layer MBUF may be disposed on the second substrate SUB2, and a first active buffer layer ABUF1 may be disposed on the multi-buffer layer MBUF.

A first metal layer ML1 and a second metal layer ML2 may be disposed on the first active buffer layer ABUF1. Here, the first metal layer ML1 and the second metal layer ML2 may be included in a light shield layer LS providing a light shield.

A second active buffer layer ABUF2 may be disposed on the first metal layer ML1 and the second metal layer ML2. A first active layer ACT1 of the driving transistor DRT may be disposed on the second active buffer layer ABUF2. The term active layer ACT refers to a semiconductor active layer and it can be comprised of one or more semiconductor layers, examples of which are described elsewhere herein.

A first gate insulating film GI1 may be disposed to cover the first active layer ACT1.

A first gate electrode GATE1 of the driving transistor DRT may be disposed on the first gate insulating film GI1. A gate material layer GM may be disposed on the first gate insulating film GI1 together with the first gate electrode GATE1 of the driving transistor DRT, at a position different from a position at which the driving transistor DRT is formed.

A first interlayer insulating film ILD1 may be disposed to cover the first gate electrode GATE1 and the gate material layer GM. A metal pattern TM1 may be disposed on the first interlayer insulating film ILD1. The metal pattern TM1 may be located at a position different from a position at which the driving transistor DRT is formed. A second interlayer insulating film ILD2 may be disposed to cover the metal pattern TM1 on the first interlayer insulating film ILD1.

Two first source-drain electrode patterns SD1 may be disposed on the second interlayer insulating film ILD2. One of the two first source-drain electrode patterns SD1 is a source node of the driving transistor DRT, and the other of the two first source-drain electrode patterns SD1 is a drain node of the driving transistor DRT. The two first source-drain electrode patterns SD1 may be electrically connected to one side and the other side of the first active layer ACT1 through contact holes in the second interlayer insulating film ILD2, the first interlayer insulating film ILD1, and the first gate insulating film GI1.

The term source-drain electrode is used herein in the broadest sense to include either a source electrode, a drain electrode or both a source and a drain electrode. As is known to those of skill in the art, a particular electrode contacting an active area of a transistor can be either source or a drain electrode and the name by which the electrode is called might change based on the electrical connection and the voltages present on various nodes of the transistor at any particular time. Thus, it is common in the art to refer to such electrodes as source-drain electrodes.

A portion of the first active layer ACT1 overlapping the first gate electrode GATE1 is a channel area. One of the two first source-drain electrode patterns SD1 may be connected to one side of the channel area in the first active layer ACT1, and the other of the two first source-drain electrode patterns SD1 may be connected to the other side of the channel area in the first active layer ACT1.

A passivation layer PAS0 is disposed to cover the two first source-drain electrode patterns SD1. Planarization layers PLN may be disposed on the passivation layer PAS0. The planarization layer PLN may include a first planarization layer PLN1 and a second planarization layer PLN2.

The first planarization layer PLN1 may be disposed on the passivation layer PAS0.

A second source-drain electrode pattern SD2 may be disposed on the first planarization layer PLN1. The second source-drain electrode pattern SD2 may be connected to one first source-drain electrode pattern (corresponding to the second node N2 of the driving transistor DRT in the subpixel SP illustrated in FIG. 3) of the two first source-drain electrode patterns SD1 through a contact hole in the first planarization layer PLN1.

A second planarization layer PLN2 may be disposed to cover the second source-drain electrode pattern SD2. Emitting devices ED may be disposed on the second planarization layer PLN2.

Reviewing the layered structure of each of the emitting devices ED, an anode AE may be disposed on the second planarization layer PLN2. The anode AE may be electrically connected to the second source-drain electrode pattern SD2 through a contact hole in the second planarization layer PLN2.

A bank BANK may be disposed to cover a portion of the anode AE. A portion of the bank BANK corresponding to the emitting area EA of the subpixel SP may be opened.

A portion of the anode AE may be exposed through an open area (i.e., the opened portion) of the bank BANK. The emitting layer EL may be located on a side surface of the bank BANK and in the open area (i.e., the opened portion) of the bank BANK. The entirety or a portion of the emitting layer EL may be located between adjacent banks BANK.

In the open area of the bank BANK, the emitting layer EL may be in contact with the anode AE. A cathode CE may be disposed on the emitting layer EL.

The anode AE, the emitting layer EL, and the cathode CE may constitute an emitting device ED. The emitting layer EL may include an organic film.

An encapsulation layer ENCAP may be disposed on the emitting device ED.

The encapsulation layer ENCAP may have a single-layer structure or a multilayer structure. For example, as illustrated in FIGS. 6 and 7, the encapsulation layer ENCAP may include a first encapsulation layer PAS1, a second encapsulation layer PCL, and a third encapsulation layer PAS2.

For example, the first encapsulation layer PAS1 and the third encapsulation layer PAS2 may be inorganic films, while the second encapsulation layer PCL may be an organic film. Among the first encapsulation layer PAS1, the second encapsulation layer PCL, and the third encapsulation layer PAS2, the second encapsulation layer PCL may be the thickest and serve as a planarization layer.

The first encapsulation layer PAS1 may be disposed on the cathode CE and most adjacent to the emitting device ED. The first encapsulation layer PAS1 may be formed of an inorganic insulating material capable of low-temperature deposition. For example, the inorganic insulating material of the first encapsulation layer PAS1 may be silicon nitride (SiNx), silicon oxide (SiOx), silicon oxynitride (SiON), aluminum oxide, or the like. Since the first encapsulation layer PAS1 is deposited in a low-temperature atmosphere, the first encapsulation layer PAS1 may prevent the emitting layer EL including an organic material vulnerable to a high-temperature atmosphere from being damaged during deposition processing.

The second encapsulation layer PCL may be formed in an area smaller than the area of the first encapsulation layer PAS1. In this case, the second encapsulation layer PCL may be formed such that both ends of the first encapsulation layer PAS1 are exposed. The second encapsulation layer PCL may serve as a buffer to reduce stress between layers due to bending of the display device 100, and may also serve to enhance planarization performance. For example, the second encapsulation layer PCL may be formed of an acrylic resin, an epoxy resin, polyimide, polyethylene, silicon oxycarbide (SiOC), or the like, or may be formed of an organic insulating material. For example, the second encapsulation layer PCL may be formed using an inkjet method.

The third inorganic encapsulation layer PAS2 may be formed on the substrate SUB including the second encapsulation layer PCL to cover a top surface and a side surface of each of the second encapsulation layer PCL and the first encapsulation layer PAS1. The third encapsulation layer PAS2 may minimize or block penetration of external moisture or oxygen into the first inorganic encapsulation layer PAS1 or the organic encapsulation layer PCL. For example, the third encapsulation layer PAS2 is formed of an inorganic insulating material such as silicon nitride (SiNx), silicon oxide (SiOx), silicon oxynitride (SiON), or aluminum oxide (Al₂O₃).

Referring to FIG. 7, in an in-cell display panel PNL in which the touch sensors TS are disposed inside the display panel PNL, the touch sensors TS may be disposed on the encapsulation layer ENCAP. The structure of each of the touch sensors will be described as follows.

A touch buffer film T-BUF may be disposed on the encapsulation layer ENCAP. The touch sensors TS may be disposed on the touch buffer film T-BUF.

Each of the touch sensors TS may include touch sensor metals TSM and a bridge metal BRG located on different layers.

A touch interlayer insulating film T-ILD may be disposed between the touch sensor metals TSM and the bridge metal BRG.

For example, the touch sensor metals TSM may include a first touch sensor metal TSM, a second touch sensor metal TSM, and a third touch sensor metal TSM disposed adjacent to each other. The third touch sensor metal TSM is present between the first touch sensor metal TSM and the second touch sensor metal TSM. When the first touch sensor metal TSM and the second touch sensor metal TSM are to be electrically connected to each other, the first touch sensor metal TSM and the second touch sensor metal TSM may be electrically connected to each other through the bridge metal BRG located on a different layer. The bridge metal BRG may be insulated from the third touch sensor metal TSM by the touch interlayer insulating film T-ILD.

When the touch sensors TS are formed on the display panel PNL, the display panel PNL may be exposed to an agent (e.g., a developing solution or an etchant) used in processing, external moisture, or the like. Since the touch sensors TS are disposed on the touch buffer film T-BUF, penetration of the agent, moisture, or the like into the emitting layer EL including an organic material during fabrication of the touch sensors TS may be prevented. Thus, the touch buffer film T-BUF may prevent the emitting layer EL vulnerable to the agent or moisture from being damaged.

In order to prevent the emitting layer EL including an organic material vulnerable to high temperature from being damaged, the touch buffer film T-BUF is formed of an organic insulating material that may be formed at a low temperature of a predetermined temperature (e.g., 100° C.) or lower and has a low permittivity of 1 to 3. For example, the touch buffer film T-BUF may be formed of an acrylic material, an epoxy-based material, or a siloxane-based material. Due to bending of the display device 100, the encapsulation layer ENCAP may be damaged, and the touch sensor metals located on the touch buffer film T-BUF may be fractured. Even in the case that the display device 100 is bent, the touch buffer film T-BUF formed of an organic insulating material and having planarization performance may prevent at least one of damage to the encapsulation layer ENCAP and fracture of the metals TSM and BRG of the touch sensors TS.

A passivation layer PAC may be disposed to cover the touch sensors TS. The passivation layer PAC may be an organic insulating film.

Next, a layered structure of the first optical area OA1 will be described with reference to FIGS. 6 and 7.

Referring to FIGS. 6 and 7, the emitting areas EA in the first optical area OA1 may have a layered structure the same as the layered structure of the emitting areas EA in the normal area NA. Thus, hereinafter, the layered structure of the first transmission areas TA1 in the first optical area OA1 will be described in detail.

Although the cathode CE is disposed in each of the emitting areas EA included in the normal area NA and the first optical area OA1, no cathode may be disposed in the first transmission areas TA1 in the first optical area OA1. That is, each of the first transmission areas TA1 in the first optical area OA1 may correspond to an open area of the cathode CE.

In addition, in each of the emitting areas included in the normal area NA and the first optical area OA1, the light shield layer LS including at least one of the first metal layer ML1 and the second metal layer ML2 is disposed. In contrast, in each of the first transmission areas TA1 in the first optical area OA1, the light shield layer LS may not be disposed. That is, each of the first transmission areas TA1 in the first optical area OA1 may correspond to an open area of the light shield layer LS.

The substrate SUB and the variety of insulating films MBUF, ABUF1, ABUF2, GI, ILD1, ILD2, PAS0, PLN (PLN1 and PLN2), BANK, ENCAP (PAS1, PCL, and PAS2), T-BUF, T-ILD, and PAC disposed in each of the emitting areas included in the normal area NA and the first optical area OA1 may also be disposed in each of the first transmission areas TA1 in the first optical area OA1 in the same manner.

However, in the emitting area EA included in the normal area NA and the first optical area OA1, a material layer having electrical conductive characteristics (e.g., a metal material layer and a semiconductor layer), except for an insulating material, may not be disposed in the first transmission areas TA1 in the first optical area OA1.

For example, referring to FIGS. 6 and 7, none of the metal material layers ML1, ML2, GATE1, GM, TM1, SD1, and SD2 and the semiconductor layer ACT1 related to the transistor may be disposed in the first transmission areas TA1.

In addition, referring to FIGS. 6 and 7, none of the anode AE and the cathode CE included in the emitting device ED may be disposed in the first transmission areas TA1. Here, the emitting layer EL may or may not be disposed in the first transmission areas TA1.

In addition, referring to FIG. 7, none of the touch sensor metals TSM and the bridge metal BRG included in the touch sensor TS may be disposed in the first transmission areas TA1 in the first optical area OA1.

Thus, since a material layer having electrical conductive characteristics (e.g., a metal material layer and a semiconductor layer) is not disposed in the first transmission areas TA1 in the first optical area OA1, the first transmission areas TA1 in the first optical area OA1 may have light transmittance. Accordingly, the first optoelectronic device 11 may perform a designated function (e.g., an image sensing function) by receiving light that has passed through the first transmission areas TA1.

Since the entirety of or a portion of the first transmission areas TA1 in the first optical area OA1 overlaps the first optoelectronic device 11, for normal operations of the first optoelectronic device 11, the transmittance of the first transmission areas TA1 in the first optical area OA1 is required to be further increased.

In this regard, in the display panel PNL of the display device 100 according to embodiments of the present disclosure, the first transmission areas TA1 in the first optical area OA1 may have a transmittance improvement structure (TIS).

Referring to FIGS. 6 and 7, a plurality of insulating films included in the display panel PNL may include: the buffer layers MBUF, ABUF1, and ABUF2 between the substrates SUB1 and SUB2 and the transistors DRT and SCT; the planarization layers PLN1 and PLN2 between the transistor DRT and the emitting device ED; the encapsulation layer ENCAP on the emitting device ED; and the like.

Referring to FIG. 7, the plurality of insulating films included in the display panel PNL may further include the touch buffer film T-BUF, the touch interlayer insulating film T-ILD, and the like on the encapsulation layer ENCAP.

Referring to FIGS. 6 and 7, the first transmission areas TA1 in the first optical area OA1 may have a structure in which the first planarization layer PLN1 and the passivation layer PAS0 are depressed downward as the transmittance improvement structure.

Referring to FIGS. 6 and 7, the first planarization layer PLN1 among the plurality of insulating films may include at least one concave-convex portion (or depressed portion). Here, the first planarization layer PLN1 may be an organic insulating film.

When the first planarization layer PLN1 is depressed downward, the second planarization layer PLN2 may substantially serve as a planarization layer. In addition, the second planarization layer PLN1 may be depressed downward. In this case, a second encapsulation layer PCL may substantially perform a planarization function.

Referring to FIGS. 6 and 7, the depressed portions of the first planarization layer PLN1 and the passivation layer PAS0 may downwardly extend through the insulating films ILD2, IDL1, and GI for forming the transistor DRT and the buffer layers ABUF1, ABUF2, and MBUF located below the insulating films ILD2, IDL1, and GI to reach a top portion of the second substrate SUB2.

Referring to FIGS. 6 and 7, the substrate SUB may include at least one recessed portion as the transmittance improvement structure. For example, in the first transmission areas TA1, the top surface of the second substrate SUB1 may be depressed or perforated.

Referring to FIGS. 6 and 7, the transmittance improvement structure may be configured such that the first encapsulation layer PAS1 and the second encapsulation layer PCL of the encapsulation layer ENCAP are also depressed downward. Here, the second encapsulation layer PCL may be an organic insulating film.

Referring to FIG. 7, the passivation layer PAC may be disposed to cover the touch sensors TS on the encapsulation layer ENCAP to protect the touch sensors TS.

Referring to FIG. 7, the passivation layer PAC may have at least one concave-convex portion in a portion thereof overlapping the first transmission areas TA1 as the transmittance improvement structure. Here, the passivation layer PAC may be an organic insulating film.

Referring to FIG. 7, each of the touch sensors TS may be comprised of a mesh-type touch sensor metal TSM. When the touch sensor metal TSM is a mesh-type sensor metal, a plurality of open areas may be present in the touch sensor metal TSM. The positions of the plurality of open areas may correspond to the positions of the emitting areas EA of the subpixels SP, respectively.

The area of the touch sensor metal TSM per unit area in the first optical area OA1 may be smaller than the area of the touch sensor metal TSM per unit area in the normal area NA so that the transmittance of the first optical area OA1 is higher than the transmittance of the normal area NA.

Referring to FIG. 7, the touch sensors TS may be disposed in the emitting areas in the first optical area OA1, and none of the touch sensors TS may be disposed in the first transmission areas TA1 in the first optical area OA1.

Next, a layered structure of the second optical area OA2 will be described with reference to FIGS. 6 and 7.

Referring to FIGS. 6 and 7, the layered structure of the emitting areas EA in the second optical area OA2 may be the same as the layered structure of the emitting areas EA in the normal area NA. Thus, hereinafter, a layered structure of the second transmission areas TA2 in the second optical area OA2 will be described in detail.

The cathode CE is disposed in each of the emitting areas EA included in the normal area NA and the second optical area OA2, while no cathode may be disposed in the second transmission areas TA2 in the second optical area OA2. That is, the second transmission areas TA2 in the second optical area OA2 may correspond to the open areas of the cathodes CE.

In addition, the light shield layer LS including at least one of the first metal layer ML1 and the second metal layer ML2 is disposed in the emitting areas EA included in the normal area NA and the second optical area OA2, while the light shield layer LS may not be disposed in the second transmission areas TA2 in the second optical area OA2. That is, the second transmission areas TA2 in the second optical area OA2 may correspond to the open areas of the light shield layer LS

When the transmittance of the second optical area OA2 is the same as the transmittance of the first optical area OA1, the layered structure of the second transmission areas TA2 in the second optical area OA2 may be completely the same as the layered structure of the first transmission areas TA1 in the first optical area OA1.

When the transmittance of the second optical area OA2 is different from the transmittance of the first optical area OA1, the layered structure of the second transmission areas TA2 in the second optical area OA2 may be partially different from the layered structure of the first transmission areas TA1 in the first optical area OA1.

For example, as illustrated in FIGS. 6 and 7, when the transmittance of the second optical area OA2 is lower than the transmittance of the first optical area OA1, the second transmission areas TA2 in the second optical area OA2 may not have the transmittance improvement structure. For example, none of the first planarization layer PLN1 and the passivation layer PAS0 may be depressed. In addition, the width of the second transmission areas TA2 in the second optical area OA2 may be narrower than the width of the first transmission areas TA1 in the first optical area OA1.

The substrate SUB and the variety of insulating films MBUF, ABUF1, ABUF2, GI, ILD1, ILD2, PAS0, PLN (PLN1 and PLN2), BANK, ENCAP (PAS1, PCL, and PAS2), T-BUF, T-ILD, and PAC disposed in the emitting areas EA included in the normal area NA and the second optical area OA2 may be equally disposed in the second transmission areas TA2 in the second optical area OA2.

However, in the emitting areas EA included in the normal area NA and the second optical area OA2, a material layer having electrical conductive characteristics (e.g., a metal material layer and a semiconductor layer), except for an insulating material, may not be disposed in the in the transmission areas TA2 in the second optical area OA2.

For example, referring to FIGS. 6 and 7, none of the metal material layers ML1, ML2, GATE1, GM, TM1, SD1, and SD2 and the semiconductor layer ACT1 related to the transistor may be disposed in the second transmission areas TA2 in the second optical area OA2.

In addition, referring to FIGS. 6 and 7, none of the anode AE and the cathode CE included in the emitting device ED may be disposed in the second transmission areas TA2 in the second optical area OA2. Here, the emitting layer EL may or may not be disposed in the second transmission areas TA2 in the second optical area OA2.

In addition, referring to FIG. 7, none of the touch sensor metal TSM and the bridge metal BRG included in the touch sensors TS may be disposed in the second transmission areas TA2 in the second optical area OA2.

Thus, since a material layer having electrical conductive characteristics (e.g., a metal material layer and a semiconductor layer) is not disposed in the second transmission areas TA2 in the second optical area OA2, the second transmission areas TA2 in the second optical area OA2 may have light transmittance. Accordingly, the second optoelectronic device 12 may perform a designated function (e.g., a function of detecting an approach of an object or a human body or a function of detecting luminous intensity of external light) by receiving light that has passed through the second transmission areas TA2.

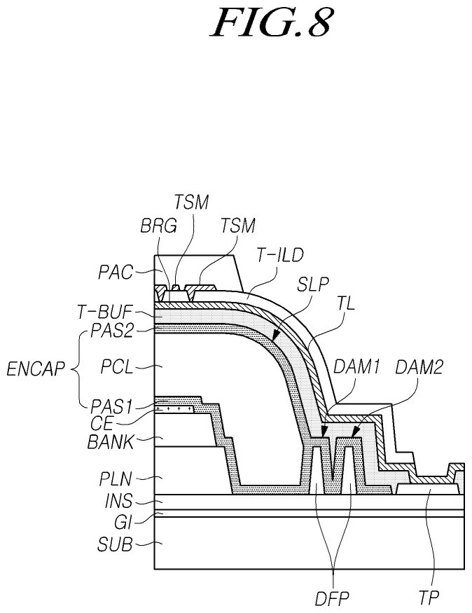

FIG. 8 is a cross-sectional diagram of a peripheral portion of the display panel PNL according to embodiments of the present disclosure.

In FIG. 8, a substrate SUB in which a first substrate SUB1 and a second substrate SUB2 are integrated is illustrated, and a bottom portion of the bank BANK is schematically illustrated. In FIG. 8, the first planarization layer PLN1 and the second planarization layer PLN2 are illustrated as a single planarization layer PLN, and the second interlayer insulating film ILD2 and the first interlayer insulating film ILD1 below the planarization layer PLN are illustrated as a single interlayer insulating film INS.

Referring to FIG. 8, the first encapsulation layer PAS1 may be disposed on the cathode CE and most adjacent to the emitting device ED. The second encapsulation layer PCL may be formed such that the area thereof is smaller than the area of the first encapsulation layer PAS1. In this case, the second encapsulation layer PCL may be formed so as to expose both ends of the first encapsulation layer PAS1.

The third inorganic encapsulation layer PAS2 may be formed on the substrate SUB on which the second encapsulation layer PCL is formed so as to cover a top surface and a side surface of each of the second encapsulation layer PCL and the first encapsulation layer PAS1.

The third encapsulation layer PAS2 minimizes or blocks penetration of external moisture or oxygen into the first inorganic encapsulation layer PAS1 or the organic encapsulation layer PCL.

Referring to FIG. 8, in the display panel PNL, one or more dams DAM1 and DAM2 may be present at or around a terminal end of a slope SLP of the encapsulation layer ENCAP in order to prevent the encapsulation layer ENCAP from collapsing. The one or more dams DAM1 and DAM2 may be present at or around the boundary between the display area DA and the non-display area NDA.

The one or more dams DAM1 and DAM2 may include a material DFP the same as the material of the bank BANK.

Referring to FIG. 8, the second encapsulation layer PCL including an organic material may only be located on the inner surface of the first dam DAM1 located innermost the dams DAM1 and DAM2. That is, the second encapsulation layer PCL may not be present on both top portions of the dams DAM1 and DAM2. Differently, the second encapsulation layer PCL including an organic material may be located at least on the top portion of the first dam DAM1 of the first and second dams DAM1 and DAM2.

The second encapsulation layer PCL may extend to and located on the top portion of the first dam DAM1. Alternatively, the second encapsulation layer PCL may extend to and located on the top portion of the second dam DAM2 by extending beyond the first dam DAM1.

Referring to FIG. 8, a touch pad TP to which the touch driver circuit TDC is electrically connected may be disposed outside of the one or more dams DAM1 and DAM2.

A touch line TL may electrically connect the touch sensor metal TSM or the bridge metal BRG of the touch electrode disposed in the display area DA to the touch pad TP.

One end of the touch line TL may be electrically connected to the touch sensor metal TSM or the bridge metal BRG, while the other end of the touch line TL may be electrically connected to the touch pad TP.

The touch line TL may extend downward along the slope SLP of the encapsulation layer ENCAP to cover the top portions of the dams DAM1 and DAM2 and reach the touch pad TP disposed outside of the dams DAM1 and DAM2.

Referring to FIG. 8, the touch line TL may be the bridge metal BRG. Alternatively, the touch line TL may be the touch sensor metal TSM.

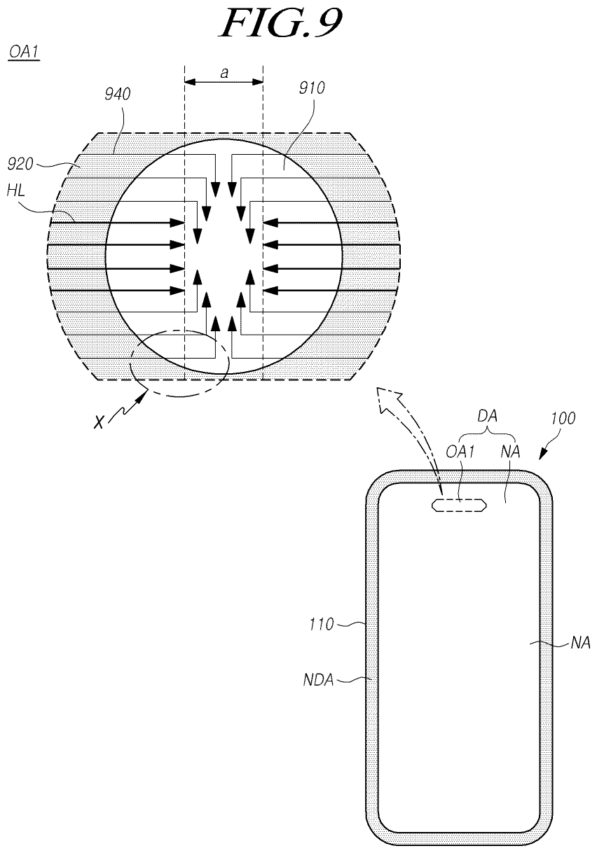

FIG. 9 is a plan diagram of the first optical area OA1 of the display device according to embodiments of the present disclosure.

Referring to FIG. 9, the first optical area OA1 may include a central area 910 and a bezel area 920 located outside of the central area 910.

The first optical area OA1 may include a plurality of horizontal lines HL. The transistors located in the bezel area 920 and the emitting devices located in the central area 910 may be connected through the plurality of horizontal lines HL.

The display device according to embodiments may include a routing structure 940. Since the display device includes the routing structure 940, the central area 910 may be increased by a predetermined area a. This is because the pixels located in the predetermined area a may be connected to the transistors located in the bezel area 920 through the routing structure 940.

The structure of the first optical areas OA1 including the routing structure 940 will be reviewed in detail as follows.

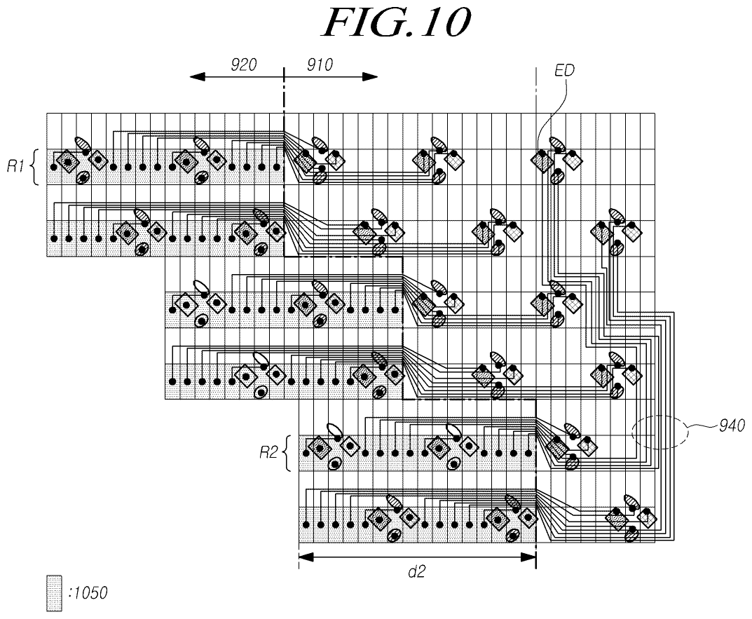

FIG. 10 is an enlarged diagram of area X in FIG. 9.

Referring to FIG. 10, the first optical area may include a plurality of emitting device ED located in the central area 910 and the bezel area 920. Since the first optical area includes the plurality of emitting device ED, the first optical area may display an image.

The first optical area may include a plurality of transistors 1050 located in the bezel area 920. None of the transistors 1050 may be located in the central area 910. Since no transistors are located in the central area 910, the central area 910 may have a higher level of transmittance.

The first optical area may include a plurality of rows, in particular, a first row R1 and a second row R2. The plurality of rows included in the first optical area may be a predetermined area crossing the first optical area in a horizontal direction and defined by the pattern of the transistors 1050.

The display device may include the emitting devices ED located in the central area 910 and in the first row R1 and transistors 1050 located in the bezel area 920 and in the second row R2.

The display device may include the routing structure 940 electrically connecting an emitting device among the emitting devices ED located in the first row R1 and to a corresponding transistor among the transistors 1050 located in the second row R2.

Since the transistor 1050 and the emitting device ED located in different rows may be connected to each other by the routing structure 940, transistors located in a row in which a greater number of transistors than emitting devices are disposed may be connected to emitting devices located in a row in which a greater number of emitting devices than transistors are disposed.

The number of the emitting devices ED that the central area 910 includes in the first row R1 may be greater than the number of the emitting devices that the central area 921 includes in the second row R2. Thus, a greater number of transistors are required to drive the emitting device ED in the first row R1, while a smaller number of transistors are required to drive the emitting devices ED in the second row R2. Thus, extra transistors not electrically connected to the emitting devices located in the second row R2, among the transistors located in the second row R2 of the bezel area 920, may be electrically connected to the emitting devices ED located in the first row R1 by the routing structure 940.

The central area 910 may be configured such that the number of pixels per area is substantially uniform across the entirety of the central area 910. The number of pixels per area being uniform across the entirety of the central area 910 means that, for example, a single pixel pattern is substantially uniform across the entirety of the central area 910. Thus, in the first row R1 having a larger area overlapping the central area 910 than the second row R2, a greater number of emitting devices ED may be located.

For example, the number of transistors 1050 that the bezel area 920 includes in the first row R1 may be substantially the same as the number of transistors 1050 that the bezel area 920 includes in the second row R2. In the above example, when the central area 910 includes a greater number of emitting devices ED in the first row R1 and a smaller number of emitting devices ED in the second row R2, a portion of the transistors 1050 in the second row R2 may be electrically connected to the emitting device ED in the first row R1 instead of being electrically connected to the emitting device ED in the second row R2.

The bezel area 920 may be configured such that the number of transistors per area is substantially uniform across the entirety of the bezel area 920. The number of pixels per area being uniform across the entirety of the bezel area 920 may mean that a single transistor pattern is substantially uniform across the entirety of the bezel area 920.

The size of an area of the bezel area 920 overlapping the first row R1 may be substantially the same as the size of an area of the bezel area 920 overlapping the second row R2. In this example, the number of the transistors 1050 located in the first row R1 of the bezel area 920 may be substantially the same as the number of the transistors 1050 located in the second row R2 of the bezel area 920.

When the bezel area 920 is configured as above, the number of the transistors 1050 located in a row of the bezel area 920 may be maintained the same, and extra transistors in a specific row may be electrically connected to extra emitting devices in another row by the routing structure 940. Thus, the central area 910 of the display device according to embodiments may be wider than that of a display device of the related art.

The display device according to embodiments of the present disclosure described as above will be briefly reviewed as follows.

The display device 100 according to embodiments of the present disclosure may include the display area DA, the emitting device ED, the transistors 1050, and the routing structure 940.

The display area DA may include the first optical area OA1 and the normal area NA. The first optical area OA1 may include the central area 910 and the bezel area 920 located outside of the central area 910. The first optical area OA1 may include the first row R1 and the second row R2.

The emitting device ED may be located in the central area 910 and in the first row R1.

The transistors 1050 may be located in the bezel area 920 and in the second row R2.

The routing structure 940 may electrically connect the emitting devices located in the central area 910 and in the first row R1 and the transistors located in the bezel area 920 and in the second row R2.

The first optical area OA1 may include the plurality of emitting devices ED located in the central area 910 and the bezel area 920.

The first optical area OA1 may include the plurality of transistors 1050 located in the bezel area 920.

None of the transistors 1050 may be located in the central area 910.

The common electrode corresponding to the cathode CE may include a first common electrode CE. The first common electrode CE may be provided to the plurality of emitting devices ED located in the central area 910.

The first common electrode CE may include first portions corresponding to the emitting areas located in the central area 910, a second portion connecting the first portions, and open areas located between the first portions and the second portion.

The display device 100 may include may include the light shield layer LS located in the central area 910 and corresponding to the emitting areas.

The central area 910 may include the plurality of emitting devices ED. The number of the emitting device ED that the central area 910 includes in the first row R1 may be much greater than the number of the emitting devices that the central area 910 includes in the second row R2.

The central area 910 may be configured such that the number of pixels per area is substantially uniform across the entirety of the central area 910. The size of an area of the central area 910 overlapping the first row R1 may be greater than the size of an area of the central area 910 overlapping the second row R2.

The bezel area 920 may include a plurality of transistors 1050. The number of the transistors 1050 that the bezel area 920 includes in the first row R1 may be substantially the same as the number of the transistors 1050 that the bezel area 920 includes in the second row R2.

The bezel area 920 may be configured such that the number of the transistors 1050 per area is substantially uniform across the entirety of the bezel area 920. The size of an area of the bezel area 920 overlapping the first row R1 may substantially the same as the size of an area of the bezel area 920 overlapping the second row R2.

The structure of the display device according to embodiments of the present disclosure as described above will be reviewed in detail as follows.

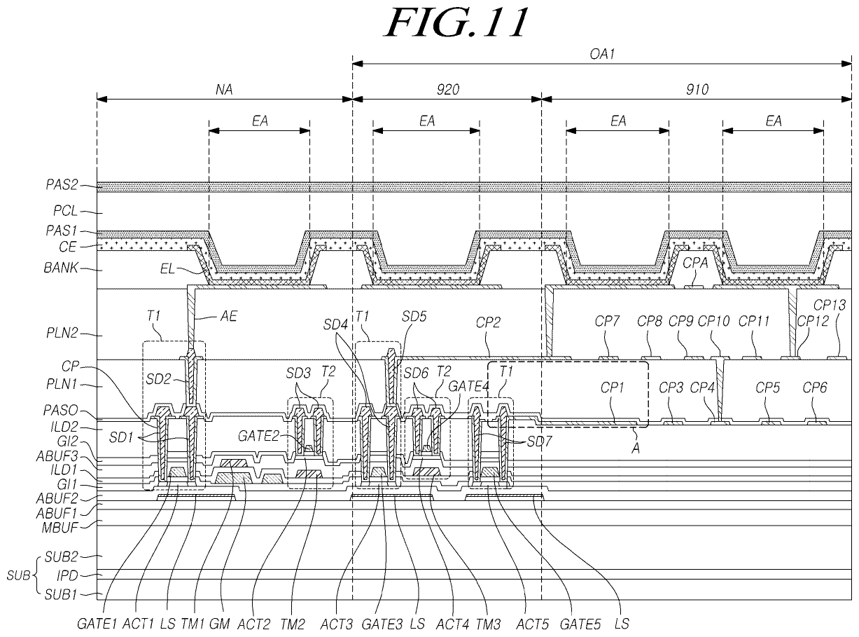

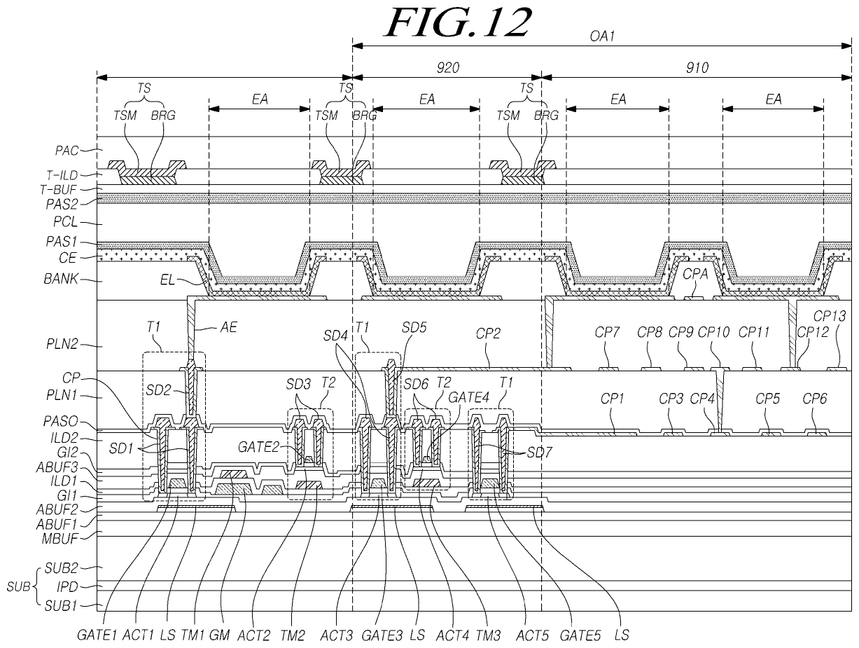

FIGS. 11 and 12 are diagrams illustrating portions of the normal area and the first optical area included in the display area of the display device according to embodiments of the present disclosure having the routing structure.

The routing structure illustrated in FIGS. 11 and 12 may be realized using a plurality of connection patterns.

FIG. 11 illustrates cross-sections of the display panel PNL in a case in which the touch sensors are present outside the display panel PNL as the touch panel, and FIG. 12 illustrates cross-sections of the display panel PNL in a case in which the touch sensors are present inside the display panel PNL.

FIGS. 11 and 12 illustrate cross-sectional structures of the normal area NA and the central area 910 and the bezel area 920 of the first optical area OA1 included in the display area DA.

With reference to FIGS. 11 and 12, a layered structure of the normal area NA will be described. The layered structure of the normal area NA illustrated in FIGS. 11 and 12 may be similar to the layered structure of the normal area NA illustrated in FIGS. 6 and 7.

Here, as illustrated in FIGS. 11 and 12, a plurality of transistors may be disposed in at least one subpixel of the normal area NA.

Specifically, a plurality of transistors T1 and T2 may be disposed in at least one subpixel of the normal area NA. Here, the plurality of transistors may include a first transistor T1 and a second transistor T2. The first transistor T1 may be a driving transistor, while the second transistor T2 may be a scanning transistor. However, the type and structure of the transistor according to embodiments of the present disclosure are not limited thereto, but the first transistor T1 may be a scanning transistor, the second transistor T2 may be a driving transistor, the first and second transistors T1 and T2 may be the same type of TFTs.

Although a structure in which two transistors are disposed in the normal area NA is illustrated in FIGS. 11 and 12, the structure according to the present embodiments is not limited thereto. Rather, a structure in which at least two transistors are disposed in each of the subpixels in the normal area NA may be used.

Referring to FIGS. 11 and 12, the substrate SUB may include a first substrate SUB1, an interlayer insulating film IPD, and a second substrate SUB2.

A variety of patterns ACT1, SD1, and GATE1 for forming transistors such as the first transistor T1, a variety of insulating films MBUF, ABUF1, ABUF2, GI, ILD1, ILD2, and PAS0, and a variety of metal patterns TM1, GM, ML1, and ML2 may be disposed on the substrate SUB.

In addition, a variety of patterns ACT1, GATE1, SD3, and SD4 included in the second transistor T2 may be disposed on the substrate SUB.

Referring to FIGS. 11 and 12, a second metal pattern TM2 may be disposed on the first interlayer insulating film ILD1.

A third active buffer layer ABUF3 may be disposed on the second metal pattern TM2.

A second active layer ACT2 of the second transistor T2 may be disposed on the third active buffer layer ABUF3.

Here, a first active layer ACT1 of the first transistor T1 and the second active layer ACT2 of the second transistor T2 may be different types.

For example, the first active layer ACT1 may include a polysilicon material, and the second active layer ACT2 may include a metal oxide material. Here, the first transistor T1 may be a thin-film transistor using a low-temperature polysilicon (LTPS), while the second transistor T2 may be an oxide semiconductor thin-film transistor. The active layers of the various transistors include respective source and drain regions.

However, the types of the transistors according to embodiments of the present disclosure are not limited thereto.

The type of the first active layer ACT1 of the first transistor T2 and the type of the second active layer ACT2 of the second transistor T2 may be the same.

For example, each of the first active layer ACT1 and the second active layer ACT2 may include a metal oxide material or a polysilicon material.

A second gate insulating film GI2 may be disposed on the second active layer ACT2.

A second gate electrode GATE2 of the second transistor T2 may be disposed on the second gate insulating film GI2.

A second interlayer insulating film ILD2 may be disposed on the second gate electrode GATE2.

Two third source-drain electrode patterns SD3 may be disposed on the second interlayer insulating film ILD2.

A portion of the second active layer ACT2 overlapping the second gate electrode GATE2 may be a channel area.

One of the two third source-drain electrode patterns SD3 may be connected to one side of the second active layer ACT2, while the other of the two third source-drain electrode patterns SD3 may be connected to the other side of the second active layer ACT2.

Referring to FIGS. 11 and 12, the second active layer ACT2 may overlap the second metal pattern TM2. Specifically, the second metal pattern TM2 may overlap the channel area of the second active layer ACT2 to block light entering the second active layer ACT2.

A passivation layer PAS0 may be disposed on the first and third source-drain electrode patterns SD1 and SD3.

In the normal area NA, a layered structure on the passivation layer PAS0 may be the same as the structure illustrated in FIGS. 6 and 7.

Specifically, the layered structure of the passivation layer PAS0, a first planarization layer PLN1, a second planarization layer PLN2, a second source-drain electrode pattern SD2, anodes AE, banks BANK, emitting layers EL, cathodes CE, and an encapsulation layer ENCAP illustrated in FIG. 11 may be the same as the layered structure of the passivation layer PAS0, the first planarization layer PLN1, the second planarization layer PLN2, the second source-drain electrode pattern SD2, the anodes AE, the banks BANK, the emitting layers EL, the cathodes CE, and the encapsulation layer ENCAP illustrated in FIG. 6.

In addition, the layered structure of the passivation layer PAS0, the first planarization layer PLN1, the second planarization layer PLN2, the second source-drain electrode pattern SD2, the anodes AE, the banks BANK, the emitting layers EL, the cathodes CE, the encapsulation layer ENCAP, the touch buffer film T-BUF, the touch sensors TS, the touch interlayer insulating film T-ILD, and the passivation layer PAC illustrated in FIG. 11 may be the same as the layered structure of the passivation layer PAS0, the first planarization layer PLN1, the second planarization layer PLN2, the second source-drain electrode pattern SD2, the anodes AE, the banks BANK, the emitting layers EL, the cathodes CE, the encapsulation layer ENCAP, the touch buffer film T-BUF, the touch sensors TS, the touch interlayer insulating film T-ILD, and the passivation layer PAC illustrated in FIG. 6.

Although the structure in which the first and second planarization layers PLN1 and PNL2 are disposed in the normal area NA and the first optical area OA1 is illustrated in FIGS. 11 and 12, only one planarization layer may be disposed in the non-display area NDA (see FIG. 2) of the display panel PNL according to embodiments of the present disclosure, unlike the structure of the normal area NA and the first optical area OA1.

Next, a layered structure of the central area 910 and the bezel area 920 of the first optical area OA1 will be described with reference to FIGS. 11 and 12.

Referring to FIGS. 11 and 12, a plurality of transistors may be disposed in the bezel area 920 of the first optical area OA1, while no transistors may be disposed in the central area 910 of the first optical area OA1.

Specifically, a plurality of first transistors T1 and a plurality of second transistors T2 may be disposed in the bezel area 920.

A variety of patterns ACT3, SD4, SD5, GATE3, ACT5, SD7, and GATE5 of the plurality of first transistors T1 disposed in the bezel area 920 may be disposed on the same layer as the variety of patterns ACT1, SD1, and GATE1 of the first transistor disposed on the normal area NA.

For example, the first active layer ACT1 in the normal area NA and a third active layer ACT3 and a fifth active layer ACT5 in the bezel area 920 may be disposed on the same layer.

A first gate electrode GATE1 in the normal area NA may be disposed on the same layer as a third gate electrode GATE3 and a fifth gate electrode GATE5 in the bezel area 920.

The first source-drain electrode patterns SD1 in the normal area NA may be disposed on the same layer as fourth source-drain electrode patterns SD4 and seventh source-drain electrode patterns SD7 in the bezel area 920.

A variety of patterns ACT4, SD6, and GATE4 of the plurality of second transistors T2 disposed in the bezel area 920 may be disposed on the same layer as the variety of patterns ACT2, SD3, and GATE2 of the second transistor disposed in the normal area NA.

For example, the second active layer ACT2 in the normal area NA and the fourth active layer ACT4 in the bezel area 920 may be disposed on the same layer.

The second gate electrode GATE2 in the normal area NA may be disposed on the same layer as the fourth gate electrode GATE4 in the bezel area 920.

The third source-drain electrode patterns SD3 in the normal area NA may be disposed on the same layer as sixth source-drain electrode patterns SD6 in the bezel area 920.

Referring to FIGS. 11 and 12, the seventh source-drain electrode patterns SD7 of some first transistors T1 among the plurality of first transistors T1 disposed in the bezel area 920 may be in contact with a first connection pattern CP1. The first connection pattern CP1 may be located below the seventh source-drain electrode patterns SD7. In addition, the fourth source-drain electrode patterns SD4 of the remaining first transistors T1 among the plurality of first transistors T1 may be in electrical contact with the fifth source-drain electrode pattern SD5.

Specifically, one of the two seventh source-drain electrode patterns SD7 of some first transistors T1 among the plurality of first transistors T1 may be in contact with and overlay the first connection pattern CP1.

The seventh source-drain electrode patterns SD7 may be disposed on the second interlayer insulating film ILD2, and the first connection pattern CPI may also be disposed on the second interlayer insulating film ILD2.

In addition, the seventh source-drain electrode patterns SD7 may be in direct contact with the first connection pattern CP1 on the second interlayer insulating film ILD2.

For example, as illustrated in FIGS. 11 and 12, the first connection pattern CP1 may be disposed directly on the second interlayer insulating film ILD2, and the seventh source-drain electrode patterns SD7 may be disposed on the first connection pattern CP1.

The first connection pattern CP1 may contain a transparent conductive material. For example, the first connection pattern CP1 may contain one of indium tin oxide (ITO), indium zinc oxide (IZO), or indium gallium zinc oxide (IGZO), but embodiments of the present disclosure are not limited thereto.

Each of the seventh source-drain electrode patterns SD7 may contain an opaque metal. For example, each of the seventh source-drain electrode patterns SD7 may contain a metal, such as Al, Au, Ag, Cu, W, Mo, Cr, Ta, or Ti, or an alloy thereof, but embodiments of the present disclosure are not limited thereto.

For example, the first connection pattern CP1 may be disposed to be in contact with the active layer ACT5 of the first transistor T1 before the seventh source-drain electrode patterns SD7 are disposed. After the first connection pattern CP1 is disposed, the seventh source-drain electrode patterns SD7 may be disposed on the first pattern CP1 to be in contact with the first pattern CP1.

A connection pattern layer CP that is formed at the same time and using the same steps and material as CP1 may be formed under one or more of the source drain electrode patterns SD1, SD3, SD4 etc. One example is shown in FIGS. 11 and 12 as layer CP under the source-drain electrode SD1.

As illustrated in FIGS. 11 and 12, the first connection pattern CP1 disposed in the bezel area 920 of the first optical area OA1 may be disposed to extend to the central area 910.

A plurality of connection patterns CP3, CP4, CP5, and CP6 may be disposed on the second interlayer insulating film ILD2 in the central area 910. These can be formed at the same time and using the same steps and material used to form CP and CP1.

Each of the plurality of connection patterns CP3, CP4, CP5, and CP6 disposed on the second interlayer insulating film ILD2 may contain a transparent conductive material. For example, each of the plurality of connection patterns CP3, CP4, CP5, and CP6 may contain one of ITO, IZO, or IGZO, but embodiments of the present disclosure are not limited thereto.

At least one of the plurality of connection patterns CP3, CP4, CP5, and CP6 may be electrically connected to the seventh source-drain electrode patterns SD7 of the first transistor T1 disposed in the bezel area 920.

In addition, the fourth source-drain electrode patterns SD4 of the remaining first transistors T1 among the plurality of first transistors T1 may be in contact with the fifth source-drain electrode pattern SD5.

The fifth source-drain electrode pattern SD5 may be disposed on the same layer as the second source-drain electrode pattern SD2 in the normal area NA.

That is, the fifth source-drain electrode pattern SD5 may be disposed on the first planarization layer PLN1.

Each of the fourth and fifth source-drain electrode patterns SD4 and SD5 disposed in the bezel area 920 of the optical area OA1 may contain an opaque metal.

For example, each of the fourth and fifth source-drain electrode patterns SD4 and SD5 may contain a metal, such as Al, Au, Ag, Cu, W, Mo, Cr, Ta, or Ti, or an alloy thereof.

Although the fourth source-drain electrode patterns SD4 and the fifth source-drain electrode pattern SD5 are illustrated as having a single-layer structure in FIGS. 11 and 12, embodiments of the present disclosure are not limited thereto.

For example, at least one of the plurality of source-drain electrode patterns disposed in the display panel may have a multi-layer structure.

The fifth source-drain electrode pattern SD5 may be in contact with the second connection pattern CP2 disposed on the first planarization layer PLN1.

The fifth source-drain electrode pattern SD5 may be disposed on the first planarization layer PLN1, and the second connection pattern CP2 may also be disposed on the first planarization layer PLN1.

In addition, the fifth source-drain electrode pattern SD5 may be in direct contact with the second connection pattern CP2 on the first planarization layer PLN1.

For example, as illustrated in FIGS. 11 and 12, the second connection pattern CP2 may be disposed on the first planarization layer PLN1, and the fifth source-drain electrode pattern SD5 may be disposed on the second connection pattern CP2.

The second connection pattern CP2 may contain a transparent conductive material. For example, the second connection pattern CP2 may contain one of ITO, IZO, or IGZO, but embodiments of the present disclosure are not limited thereto.

The fifth source-drain electrode pattern SD5 may contain an opaque metal. For example, the fifth source-drain electrode pattern SD5 may contain a metal such as Al, Au, Ag, Cu, W, Mo, Cr, Ta, or T1 or an alloy thereof, but embodiments of the present disclosure are not limited thereto.

For example, the second connection pattern CP2 may be disposed to be in contact with the fourth source-drain electrode pattern SD4 before the fifth source-drain electrode pattern SD5 is disposed. After the second connection pattern CP2 is formed and disposed on the PNL1 then, the fifth source-drain electrode pattern SD5 may be formed and disposed on the second connection pattern CP2 to be in contact with the second connection pattern CP2. In a similar manner as was done in forming CP and CP1 at the same time in different locations, a connection pattern layer that is formed at the same time as the layer CP2 may be formed under the second source-drain electrode pattern SD2, as shown in FIGS. 11 and 12.

As illustrated in FIGS. 11 and 12, the second connection pattern CP2 disposed in the bezel area 920 of the first optical area OA1 may be disposed to extend to the central area 910.

A plurality of connection patterns CP7, CP8, CP9, CP10, CP11, CP12, and CP13 may be disposed on the first planarization layer PLN1 in the central area 910.

Each of the plurality of connection patterns CP7, CP8, CP9, CP10, CP11, CP12, and CP13 disposed on the first planarization layer PLN1 may contain a transparent conductive material. For example, each of the plurality of connection patterns CP7, CP8, CP9, CP10, CP11, CP12, and CP13 may contain one of ITO, IZO, or IGZO, but embodiments of the present disclosure are not limited thereto.

At least at least one of the plurality of connection patterns CP7, CP8, CP9, CP10, CP11, CP12, and CP13 may be electrically connected to the driving transistor DRT disposed in the bezel area 920, like the second connection pattern CP2.

In addition, as illustrated in FIGS. 11 and 12, at least one among the plurality of connection patterns CP3, CP4, CP5, and CP6 disposed on the second interlayer insulating film ILD2 in the central area 910 may be in contact with one of the plurality of connection patterns CP7, CP8, CP9, CP10, CP11, CP12, and CP13 disposed on the first planarization layer PLN1 through a contact hole provided in the first planarization layer PLN1.

In other words, at least one among the plurality of connection patterns CP7, CP8, CP9, CP10, CP11, CP12, and CP13 disposed on the first planarization layer PLN1 may be electrically connected to one among the plurality of connection patterns CP3, CP4, CP5, and CP6 disposed on the second interlayer insulating film ILD2, thereby being electrically connected to the first transistor T1 disposed in the bezel area 920.

That is, the plurality of connection patterns CP7, CP8, CP9, CP10, CP11, CP12, and CP13 disposed on the first planarization layer PLN1 may be electrically connected to the first transistor T1 disposed in the bezel area 920 through the connection patterns CP3, CP4, CP5, and CP6 disposed on the second interlayer insulating film ILD2, or may be electrically connected to the fifth source-drain electrode pattern SD5 connected to the fourth source-drain electrode patterns SD4 of the first transistor T1, together with the second electrode pattern CP2.

As illustrated in FIGS. 11 and 12, the seventh source-drain electrode patterns SD7 and the plurality of connection patterns CP1, CP3, CP4, CP5, and CP6 containing different materials may be disposed on the same layer (e.g., the second interlayer insulating film ILD2) in a configuration in which the seventh source-drain electrode patterns SD7 are in contact with at least one among the connection patterns CP1, CP3, CP4, CP5, and CP6.

In addition, the fifth source-drain electrode pattern SD5 and the connection patterns CP2, CP7, CP8, CP9, CP10, CP11, CP12, and CP13 containing different materials may be disposed on the same layer (e.g., the first planarization layer PLN1) in a configuration in which the fifth source-drain electrode pattern SD5 is in contact with at least one among the connection patterns CP2, CP7, CP8, CP9, CP10, CP11, CP12, and CP13.

That is, a source-drain electrode pattern and a connection pattern containing different materials may be disposed in the bezel area 920 of the first optical area OA1 such that the source-drain electrode pattern is in contact with the connection patterns, whereby the process may be simplified.

Specifically, in order to form two configurations containing different materials to be in contact with each other, a method of disposing an insulating film between the two configurations and allowing the two configurations to be in contact with each other through a contact hole is typically used.

However, in the display device according to embodiments of the present disclosure, the source-drain electrode pattern and the connection pattern containing different materials are disposed on the same layer to be in contact with each other in the bezel area 920 of the first optical area OA1. Thus, the insulating film including the contact hole may be removed between the source-drain electrode pattern and the connection pattern. Therefore, it is possible to reduce the thickness of the display device and omit two mask processes.

For example, by removing the insulating film that may be disposed between the plurality of connection patterns CP1, CP3, CP4, CP5, and CP6 and the seventh source-drain electrode patterns SD7, it is possible to reduce the thickness and omit the process of forming a contact hole through which the seventh source-drain electrode patterns SD7 may be in contact with the plurality of connection patterns CP1, CP3, CP4, CP5, and CP6.

In addition, by removing the insulating film that may be disposed between the plurality of connection patterns CP2, CP7, CP8, CP9, CP10, CP11, CP12, and CP13 and the fifth source-drain electrode pattern SD5, it is possible to reduce the thickness of the display device and omit the process (i.e., the second mask process) of forming a contact hole through which the fifth source-drain electrode pattern SD5 may be in contact with the plurality of connection patterns CP2, CP7, CP8, CP9, CP10, CP11, CP12, and CP13.

Referring to FIGS. 11 and 12, the second planarization layer PLN2 may be disposed on the first planarization layer PLN1.

The anodes AE of the emitting devices ED may be disposed on the second planarization layer PLN2.

The anodes AE may contain a transparent conductive material. For example, the anodes AE may contain one of ITO, IZO, or IGZO, but embodiments of the present disclosure are not limited thereto.

The anodes AE disposed in the first optical area OA1 may be electrically connected to the first transistors T1 disposed in the bezel area 920 of the first optical area OA1.

Although not shown in the drawings, the anodes AE of the emitting devices ED disposed in the bezel area 920 of the first optical area OA1 may be electrically connected to the first transistors T1 disposed in the bezel area 920.

In addition, the anodes AE of the emitting devices ED disposed in the central area 910 of the first optical area OA1 may be electrically connected to the first transistors T1 disposed in the bezel area 920.

For example, as illustrated in FIGS. 11 and 12, at least one anode among the anodes AE disposed on the second planarization layer PLN2 in the central area 910 may be electrically connected to a connection pattern (e.g., the second connection pattern CP2 or CP12) disposed on the first planarization layer PLN1 through a contact hole. Here, the connection pattern to which the anode AE is electrically connected may be a connection pattern in contact with the fifth source-drain electrode pattern SD5 of the first transistor T1 disposed in the bezel area 920, together with the second connection pattern CP2.

In addition, at least one other anode among the anodes AE may be electrically connected to a connection pattern (e.g., CP10) in contact with a connection pattern (e.g., CP4) disposed on the second interlayer insulating film ILD2, among the connection patterns disposed on the first planarization film PNL1. Here, the connection pattern CP4 disposed on the second interlayer insulating film ILD2 may be a connection pattern in contact with the fourth source-drain electrode pattern SD4 of the driving transistor DRT disposed in the bezel area 920.

In this manner, the anodes AE disposed in the central area 910 and the bezel area 920 may be electrically connected to the driving transistor DRT disposed in the bezel area 920.

In the normal area NA and the first optical area OA1, banks BANK not overlapping the emitting areas EA may be disposed on the second planarization layer PLN2.

The area in which the banks BANK are disposed may be a non-display area.

In addition, an additional connection pattern CPA may be disposed between the second planarization layer PLN2 and the bank BANK in the first optical area 910.

The additional connection pattern CPA may be disposed on the same layer as the anode AE, and contain the same material as the anode AE. In other words, the additional connection pattern CPA may be formed concurrently in a process of forming the anode AE.

The additional connection pattern CPA may serve to connect at least two anodes AE on the second planarization layer PLN2.

Here, the anodes AE connected through the additional connection pattern CPA may be anodes AE located in emitting areas from which the same color of light is emitted.

The additional connection pattern CPA may be electrically connected to at least one connection pattern among the connection patterns (i.e., connection patterns disposed on the second interlayer insulating film ILD2 or the first planarization film PLN1) electrically connected to the driving transistor DRT disposed in the bezel area 920.

That is, another portion of the anode AE may be electrically connected to the driving transistor DRT disposed in the bezel area 920 through the additional connection pattern CPA disposed on the second planarization layer PLN2.

Although the anode AE of the emitting device ED is illustrated as having a single-layer structure in FIGS. 11 and 12, embodiments of the present disclosure are not limited thereto.

The anode AE may have a multilayer structure. For example, the anode AE may have a structure comprised of three layers, in which a reflective electrode is disposed between transparent conductive material layers.

As illustrated in FIGS. 11 and 12, the emitting layer EL and the cathode CE may be disposed on the anode AE.

The encapsulation layer ENCAP may be disposed on the cathode CE.

In addition, as illustrated in FIGS. 11 and 12, the touch buffer film T-BUF, the touch sensors TS, the touch interlayer insulating film T-ILD, and the passivation layer PAC may be disposed on the encapsulation layer ENCAP.

As illustrated in FIGS. 11 and 12, the touch sensors TS may be disposed in the normal area NA and the bezel area 920 of the first optical area OA1 but no touch sensors may be disposed in the central area 910. However, the display device according to embodiments of the present disclosure is not limited thereto, but the touch sensor TS may be disposed in a portion of the central area 910.

The touch sensor TS may be disposed not to overlap the emitting area EA of the display panel.

Although not shown in FIGS. 11 and 12, a color filter layer may be disposed on the touch sensor TS.

The color filter layer may be disposed to correspond the emitting area EA in the normal area NA.

However, the structure of the display device according to embodiments of the present disclosure is not limited thereto, but the color filter layer may be disposed to correspond to a portion of the emitting area EA in the first optical area OA1 as required. When the color filter layer is disposed in the first optical area OA1, the area, position, and thickness of the first optical area OA1 may be variously selected in consideration of the transmittance of the first optical area OA1.

In addition, although the structure of the normal area NA and the first optical area OA1 has mainly been described with reference to FIGS. 11 and 12, the second optical area OA2 may also have a structure corresponding to the structure of the first optical area OA1.

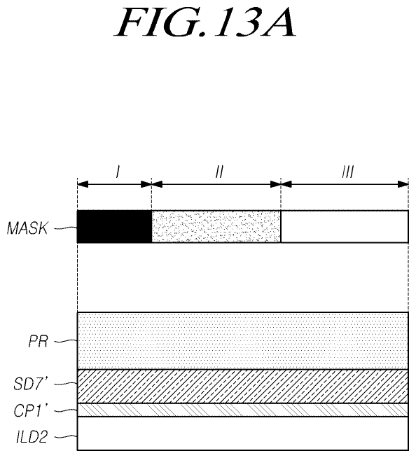

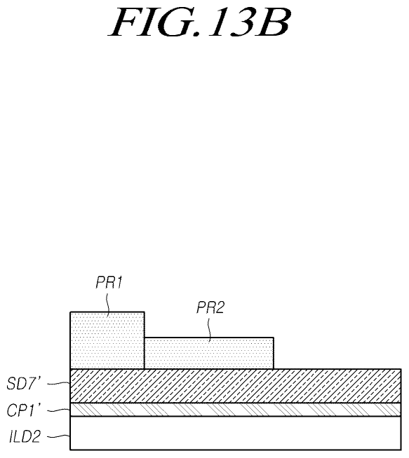

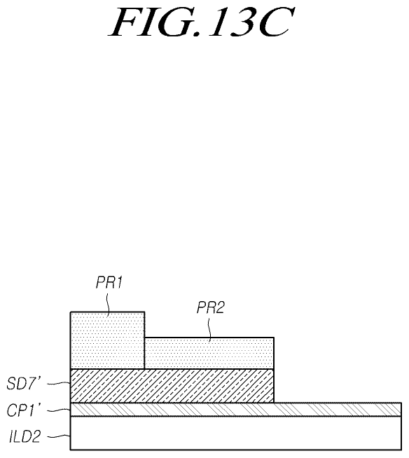

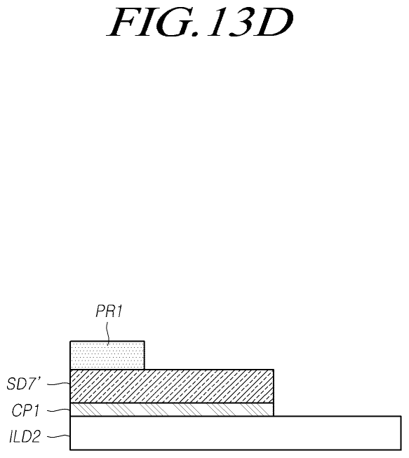

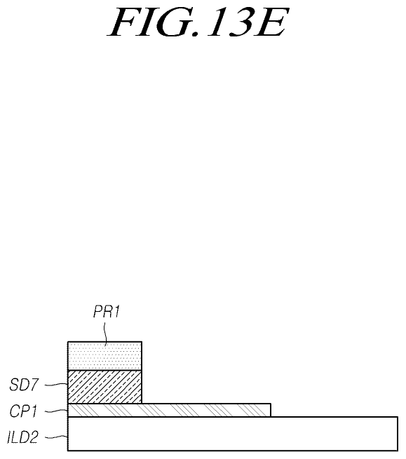

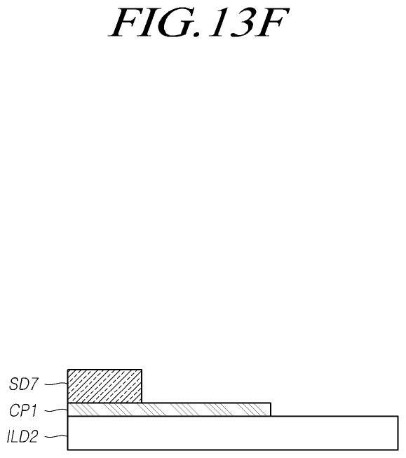

FIGS. 13A to 13F are cross-sectional diagrams specifically illustrating a process of forming the first connection pattern CP1 and the seventh source-drain electrode patterns SD7 in area A illustrated in FIG. 11.

As illustrated in FIG. 13A, a first connection pattern layer CP1′ and a seventh source-drain electrode layer SD7′ may be sequentially layered on the entire surface of the substrate SUB on which the second gate electrode GATE2 in the normal area NA, the fourth gate electrode GATE4 in the bezel area 920, and the second interlayer insulating film ILD2 on the second gate electrode GATE2 and the fourth gate electrode GATE4 are formed.

Here, the first connection pattern layer CP1′ may contain a transparent conductive material. For example, the first connection pattern layer CP1′ may contain one of ITO, IZO, or IGZO, but embodiments of the present disclosure are not limited thereto.

The seventh source-drain electrode layer SD7′ may be formed of a low-resistance opaque metal such as Al, Au, Ag, Cu, W, Mo, Cr, Ta, or T1 or an alloy thereof, but embodiments of the present disclosure are not limited thereto. In addition, the seventh source-drain electrode layer may have a multilayer structure in which two or more low-resistance opaque metals as described above are layered.

In addition, a photoresist PR formed of a photosensitive material is provided on the seventh source-drain electrode layer SD7′, and then light is selectively applied to the photoresist PR through a half tone mask MASK.

Here, the half tone mask MASK is provided with a blocking area I blocking the entirety of emitted light, a half tone area II allowing a portion of emitted light to pass therethrough while blocking the remaining portion of emitted light, and a transmission area III allowing the entirety of emitted light to pass therethrough. Only the light that has passed through the half tone mask MASK is applied to the photoresist PR.

Afterwards, when the photoresist PR exposed to light through the half tone mask MASK is developed, a first photoresist pattern PR1 and a second photoresist pattern PR2 having predetermined thicknesses remain in areas entirely or partially shielded from light through the blocking area I and the half tone area II, while the photoresist PR in an area corresponding to the transmission area III allowing the entirety of emitted light to pass therethrough is completely removed, thereby exposing the surface of the seventh source-drain electrode layer SD7′.

Here, the thickness of the first photoresist pattern PR1 formed in the area corresponding to the blocking area I is higher than the thickness of the second photoresist pattern PR2 formed in the area corresponding to the half tone area II. In addition, the photoresist PR in the area corresponding to the transmission area III allowing the entirety of emitted light to pass therethrough is completely removed. This is because a positive photoresist was used. However, the present disclosure is not limited thereto, and a negative photoresist may also be used.

Afterwards, as illustrated in FIG. 13C, the seventh source-drain electrode layer SD7′ and the first connection pattern layer CP1′ below the first photoresist pattern PR1 and the second photoresist pattern PR2 may be selectively etched using the first photoresist pattern PR1 and the second photoresist pattern PR2 as a mask. For example, when the seventh source-drain electrode layer SD7′ and the first connection pattern layer CP1′ are formed of different materials and are required to be etched by different methods, the seventh source-drain electrode layer SD7′ may be removed by dry etching and then the first connection pattern layer CP1′ may be removed by wet etching. However, embodiments of the present disclosure are not limited thereto. For example, the seventh source-drain electrode layer SD7′ and the first connection pattern layer CP1′ may be etched by the same method.

After the seventh source-drain electrode layer SD7′ and the first connection pattern layer CP1′ are removed, when an ashing process of removing a portion of the first photoresist pattern PR1 and the second photoresist pattern PR2 is performed, the second photoresist pattern PR2 in the area corresponding to the half tone area II is completely removed as illustrated in FIG. 13D.

Afterwards, as illustrated in FIG. 13E, a portion of the remaining seventh source-drain electrode layer SD7′ may be removed using the remaining first photoresist pattern PR1 as a mask. Afterwards, as illustrated in FIG. 13F, when an ashing process of removing the first photoresist pattern PR1 is performed, the first connection pattern CP1 and the seventh source-drain electrode pattern SD7 may be formed on the substrate SUB on which the second interlayer insulating film ILD2 is formed.

For example, when the first connection pattern CP1 is disposed on the seventh source-drain electrode pattern SD7, a second mask process is required to be performed to form the first connection pattern CP1 after the seventh source-drain electrode pattern SD7 is formed by a first mask process. However, according to embodiments of the present disclosure, both the first connection pattern CP1 and the seventh source-drain electrode pattern SD7 may be formed by a single mask process using the half tome mask, and thus process simplification may be obtained.

In addition, when the second connection pattern CP2 and the fifth source-drain electrode pattern SD5 are formed on the first planarization layer PLN1, the second connection pattern CP2 and the fifth source-drain electrode pattern SD5 may also be formed by a single mask process using a half tone mask in the same manner as forming the first connection pattern CP1 and seventh source-drain electrode pattern SD7. Thus, the mask process may be additionally reduced.

FIGS. 13A-13F show an example of a location on the IDL2 that is flat top surface that has no contact holes therein. As will be appreciated, in some locations, a contact hole to the source and drain regions of one or more transistors may be formed in the IDL2 prior to the connection pattern CP being deposited. Therefore, when CP1 is deposited on the top surface of the IDL2, it will enter the contact hole, be formed on all sides of the contact hole and also reach the bottom which has the exposed source and drain regions of the active areas of the transistor, for example ACT5 of T1 as shown in FIG. 11. The connection pattern CP, CP1, etc. will then be in direct contact with at least one source-drain region of the active area of the transistor T1 and the source-drain electrode pattern, such as SD1, SD3, SD7 will overlay the connection pattern CP, CP1, etc. and be in electrical contact with the source drain regions of the respective transistors.

The display device according to the present disclosure may include a display panel including a display area (DA) including a first optical area (OA1), the first optical area (OA1) including a central area (910) and a bezel area (920) located outside of the central area (910), and a normal area (NA) located outside of the first optical area (OA1). The display panel may include a plurality of emitting devices (ED) disposed in the central area (910), a plurality of emitting devices (ED) disposed in the bezel area (920), and a plurality of transistors disposed in the bezel area (920) and including a plurality of source-drain electrode patterns (SD4, SD5). A connection pattern (CP1, CP2) may extend from the bezel area (920) to a portion of the central area (910). The connection pattern (CP1, CP2) may be located below at least one of the source-drain electrode patterns (SD4, SD5) and in contact with the source-drain electrode patterns (SD4, SD5).

Some transistors among the plurality of transistors disposed in the bezel area (920) may be electrically connected to the plurality of emitting devices (ED) disposed in the bezel area (920), while the remaining transistors among the plurality of transistors disposed in the bezel area (920) may be electrically connected to the plurality of emitting devices (ED) disposed in the central area (910).

The source-drain electrode patterns (SD4, SD5, SD7) may be formed of a different material from the connection pattern (CP1 to CP13). For example, the source-drain electrode patterns (SD4, SD5, SD7) may contain an opaque metal, while the connection pattern (CP1 to CP13) may contain a transparent conductive material.

The source-drain electrode patterns may include a fourth source-drain electrode pattern (SD4), a fifth source-drain electrode pattern (SD5) electrically connected to the fourth source-drain electrode pattern (SD4), and a seventh source-drain electrode pattern (SD7) disposed on the same layer as the fourth source-drain electrode pattern (SD4). The connection patterns may include first and second connection patterns (CP1, CP2) and a plurality of connection patterns (CP3 to CP 13). Here, at least two of the first and second connection patterns (CP1, CP2) and the plurality of connection patterns (CP3 to CP 13) may be disposed on different layers.

The display panel (PNL) may include a first insulating film (ILD2) disposed on a substrate, a seventh source-drain electrode pattern (SD7) disposed on the first insulating film (ILD2), and a first connection pattern (CP1) disposed on the same layer as the seventh source-drain electrode pattern (SD7). The first connection pattern (CP1) may be in contact with the seventh source-drain electrode pattern (SD7).

The first connection pattern (CP1) may be in contact with the bottom surface of the seventh source-drain electrode pattern (SD7).

The first connection pattern (CP1) may be in direct contact with at least one active layer (ACT5) of the plurality of transistors in the bezel area (920).

The display panel (PNL) may further include a second insulating film (PLN1) disposed on the seventh source-drain electrode pattern (SD7) and the first connection pattern (CP1) and a plurality of connection patterns (CP7, CP8, CP9, CP10, CP11, CP12, CP13) disposed on the second insulating film. The first connection pattern (CP1) may be electrically connected to at least one second connection pattern among the plurality of second connection patterns (CP7, CP8, CP9, CP10, CP11, CP12, CP13).

The display panel (PNL) may further include a third insulating film (PLN2) disposed on the second insulating film (PLN1). A connection pattern disposed on the second insulating film (PLN1) and electrically connected to the first connection pattern (CP1) may be electrically connected to anodes AE of some emitting devices among the plurality of emitting devices (ED) in the central area (910) disposed on the third insulating film (PLN2).

The display panel (PNL) may include a first insulating film (ILD2) and a second insulating film (PLN1). The second insulating film (PLN1) may be disposed (or located) on the first insulating film (ILD2). The display panel (PNL) may include a first insulating film (ILD2) disposed on a substrate (SUB1), a fourth source-drain electrode pattern (SD4) disposed on the first insulating film (ILD2), a second insulating film (PLN1) disposed on a fourth source-drain electrode pattern (SD4), a source-drain electrode pattern (SD5) electrically connected to the fourth source-drain electrode pattern (SD4), and a second connection pattern (CP2) disposed on the same layer as the source-drain electrode pattern (SD5). The second connection pattern (CP2) may be in direct contact with the fifth source-drain electrode pattern (SD5). The second connection pattern (CP2) may be in contact with a bottom surface of the source-drain electrode pattern (SD5).

The display panel (PNL) may further include a third insulating film (PLN2) on the second insulating film (PLN1). The third insulating film (PLN2) may be disposed on the fifth source-drain electrode pattern (SD5) and the second connection pattern (CP2). Anodes (AE) of some emitting devices among the plurality of emitting devices (ED) in the central area (910) disposed on the third insulating film (PLN2) may be electrically connected to the second connection pattern (CP2).

The display panel (PNL) may further include an additional connection pattern (CPA) disposed on the same layer as the anodes (AE). The additional connection pattern (CPA) is connected to at least one anode among the anodes (AE) of the plurality of emitting devices (ED). The additional connection pattern (CPA) may be electrically connected to a first transistor (T1) disposed in the bezel area (920) through the connection pattern (CP1 to CP13).

The display panel (PNL) may further include an additional connection pattern (CPA) electrically connecting anodes (AE) of some emitting devices among the plurality of emitting devices (ED). The same color of light may be emitted from areas in which the anodes (AE) connected through the additional connection pattern (CPA) are disposed.

The display device may include a first optoelectronic device disposed below the display panel and overlapping at least a portion of the first optical area (OA1) of the display area DA.

The display area (DA) may further include a second optical area (OA2) different from the first optical area (OA1) and the normal area (NA). The display device may further include a second optoelectronic device located below the display panel and overlapping at least a portion of the second optical area (OA2). The normal area (NA) may or may not be disposed between the first optical area (OA1) and the second optical area (OA2).

In the display panel (PNL), an encapsulation layer may be located in the display area (DA). The display panel (PNL) may further include a first touch electrode and a second touch electrode on the encapsulation layer. Mutual capacitance (Cm) may be generated between the first touch electrode and the second touch electrode. A circuit for touch sensing (i.e., a touch sensing circuit) may detect the occurrence of a touch and determine a touch position by detecting a change in the mutual capacitance between the first touch electrode and the second touch electrode.

According to embodiments of the present disclosure having the above-described structure, in the display panel and the display device, the plurality of transistors may be disposed in the bezel area in the optical area and no transistors may be disposed in the central area of the optical area, thereby improving the transmittance of the central area.

In addition, according to embodiments of the present disclosure, in the display panel and the display device, the source-drain electrode pattern of the transistor disposed in the optical area may be disposed on the same layer as the connection pattern formed of a different material as the source-drain electrode pattern, thereby reducing the thickness and simplifying the process.

As set forth above, embodiments of the present disclosure have been described in detail with reference to the accompanying drawings. However, the present disclosure is not limited to the foregoing embodiments but a variety of modifications are possible without departing from the principle thereof. Thus, the foregoing embodiments disclosed herein should be interpreted as being illustrative, while not being limitative, of the principle and scope of the present disclosure. Respective features of embodiments of the present disclosure may be partially or entirely coupled or combined with each other and, as will be apparent to those having ordinary knowledge in in the art, may work in concert with each other or may operate in a variety of technical methods. In addition, respective embodiments may be carried out independently or may be associated with and carried out in concert with other embodiments. The scope of the present disclosure should be construed based on the appended Claims, and all technical ideas within the scope of equivalents thereof should be construed as being included within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel having a display area that includes a first optical area, the first optical area including a central area and a bezel area located outside of the central area, and the display area also including a normal area located outside of the first optical area,
wherein the display panel comprises:
a plurality of emitting devices disposed in the central area;
a plurality of emitting devices disposed in the bezel area;
a plurality of transistors disposed in the bezel area,
a plurality of source-drain electrode patterns including a first source drain electrode pattern; and
a connection pattern extending from the bezel area to a portion of the central area, and
wherein the connection pattern is located below at least one source-drain electrode pattern of the plurality of source-drain electrode patterns and in contact with the first source-drain electrode pattern.

2. The display device according to claim 1, wherein a first set of transistors among the plurality of transistors disposed in the bezel area are electrically connected to the plurality of emitting devices disposed in the bezel area, and
a second set of transistors among the plurality of transistors disposed in the bezel area are electrically connected to the plurality of emitting devices disposed in the central area.

3. The display device according to claim 1, wherein at least one source-drain electrode pattern of the plurality of source-drains patterns is formed of a different material from the connection pattern.

4. The display device according to claim 3, wherein the at least one source-drain electrode pattern of the plurality of source-drains patterns includes an opaque metal and the connection pattern includes a transparent conductive material.

5. The display device according to claim 1, wherein the plurality of source-drains patterns includes a second source-drain electrode pattern disposed on the same layer as the first source-drain electrode pattern and a third source-drain electrode pattern electrically connected to the first source-drain electrode pattern, and
the connection pattern includes first, second and third connection patterns, at least two patterns among the first to third connection patterns being disposed on different layers.

6. The display device according to claim 1, wherein the display panel further includes a first insulating film disposed on the substrate,
the first source-drain electrode pattern is disposed on the first insulating film, and
the first connection pattern is disposed on the same layer as the first source drain electrode pattern and is in contact with the first source drain electrode pattern.

7. The display device according to claim 6, wherein the first connection pattern is in contact with a bottom surface of the first source-drain electrode pattern.

8. The display device according to claim 7, wherein the first connection pattern is in direct contact with at least one active layer of the plurality of transistors in the bezel area.

9. The display device according to claim 8, wherein the display panel further includes a second insulating film disposed on the first source-drain electrode pattern and the first connection pattern and a plurality of connection patterns disposed on the second insulating film,
the first connection pattern being electrically connected to at least one connection pattern among the plurality of second connection patterns.

10. The display device according to claim 9, wherein the display panel further includes a third insulating film disposed on the second insulating film,
wherein the second connection pattern disposed on the second insulating film and electrically connected to the first connection pattern is electrically connected to anodes of some emitting devices among the plurality of emitting devices in the central area disposed on the third insulating film.

11. The display device according to claim 5, wherein the display panel further includes a first insulating film and a second insulating film disposed on the first insulating film,
the second source-drain electrode pattern is disposed on first insulating film,
the second insulating film is disposed on the second source-drain electrode pattern,
the third source-drain electrode pattern is electrically connected to the second source-drain electrode pattern,
the third connection pattern is disposed on the same layer as the third source-drain electrode pattern, and
the third connection pattern is in direct contact with the second source-drain electrode pattern and the third source-drain electrode pattern.

12. The display device according to claim 11, wherein the third connection pattern is in contact with a bottom surface of the third source-drain electrode pattern.

13. The display device according to claim 12, wherein the display panel further includes a third insulating film disposed on the third source-drain electrode pattern and the third connection pattern, and
anodes of some emitting devices among the plurality of emitting devices in the central area disposed on the third insulating film are electrically connected to the third connection pattern.

14. The display device according to claim 1, wherein the display panel further includes an additional connection pattern electrically connecting anodes of some emitting devices among the plurality of emitting devices, and
the same color of light is emitted from emitting areas in which the anodes connected through the additional connection pattern are disposed.

15. The display device according to claim 1, wherein the display panel further includes an additional connection pattern disposed on the same layer as an anode of each of the plurality of emitting devices,
the additional connection pattern is electrically connected to at least one anode among the anodes of the plurality of emitting devices, and
the additional connection pattern is electrically connected to a driving transistor disposed in the bezel area through the connection pattern.

16. The display device according to claim 1, further comprising a first optoelectronic device disposed below the display panel and overlapping at least a portion of the first optical area of the display area.

17. The display device according to claim 1, wherein the display area further includes a second optical area different from the first optical area and the normal area,
the display device further comprising a second optoelectronic device disposed below the display panel and overlapping at least a portion of the second optical area,
wherein the normal area is or is not disposed between the first optical area and the second optical area.

18. The display device according to claim 1, wherein the display area further comprises:
an encapsulation layer disposed on the display area; and
a first touch electrode and a second touch electrode disposed on the encapsulation layer.

19. The display device according to claim 18, further comprising a circuit detecting an occurrence of a touch and determining a touch position by detecting a change in mutual capacitance between the first touch electrode and the second touch electrode.

20. A display panel comprising:
a display area having a first optical area that includes a central area and a bezel area located outside of the central area, the display area also including a normal area located outside of the first optical area, the display panel comprising:
a plurality of light emitting elements disposed in the central area;
a plurality of light emitting elements disposed in the bezel area;
a plurality of transistors disposed in the bezel area, each transistor including a semiconductor active area having source-drain regions therein;
an electrically insulating layer overlying the plurality of transistors, the electrically insulating layer having a top surface;
a contact hole extending through the electrically insulating layer to expose an active area of at least one transistor of the plurality of transistors;
a first connection pattern overlaying and in contact with the electrical insulating layers and also overlying and in contact with at least one of the plurality of source-drain electrode patterns in the bezel area, the connection pattern including a second conductive metal that is different from the first conductive metal, the first connection pattern having a first portion extending through the electrically insulating layer and contacting the respective source-drain regions of the respective transistors and a second portion overlying and in contact with the top surface of the electrically insulating layer; and
a plurality of source-drain electrode patterns overlying the plurality of transistors disposed in the bezel area and having a first portion extending through the electrically insulating layer, overlying on and contacting the connection pattern in the contact holes and a second portion overlying and in contact with the second portion of the connection pattern that is on the top surface of the electrically insulating layer.

21. The display panel of claim 20 wherein the electrically insulating layer is a planarization layer having the top surface thereof planar.

22. The display panel of claim 20 further including:
a planarization layer overlying the electrically insulating layer, the planarization layer being an electrical insulator and having a top surface thereof that is planar.

23. The display panel of claim 22 further including:
a second contact hole extending through the planarization layer overlying the electrically insulating layer at least one source-drain electrode pattern;
a second connection pattern overlaying and in contact with the planarization layer and in contact with at least one of the plurality of source-drain electrode patterns in the bezel area, the connection pattern including a second conductive metal that is different from the first conductive metal, the second connection pattern having a first portion extending through the planarization layer overlying and contacting the respective source-drain electrodes of the respective transistors and a second portion overlying and in contact with the top surface of the planarization layer; and
a plurality of source-drain electrode patterns overlying the second connection pattern having a first portion overlying on and contacting the connection pattern in the second contact hole and a second portion overlying and in contact with the second portion of the second connection pattern that is on the top surface of the planarization layer.
